(19) United States
(12) Patent Application Publication
(10) Pub. No.: US 2023/0028653 A1
(43) Pub. Date: Jan. 26, 2023

(54) Semiconductor Device and Method of Forming Same

(71) Applicant: Taiwan Semiconductor Manufacturing Co., Ltd., Hsinchu (TW)

(72) Inventors: Chih-Teng Hsu, Taoyuan (TW); Chien-I Kuo, Chiayi County (TW); Chii-Horng Li, Zhubei City (TW); Yee-Chia Yeo, Hsinchu (TW)

(21) Appl. No.: 17/567,659

(22) Filed: Jan. 3, 2022

Related U.S. Application Data
(60) Provisional application No. 63/224,905, filed on Jul. 23, 2021.

(51) Int. Cl. H01L 29/66; H01L 29/06; H01L 29/423; H01L 29/786; H01L 21/02

(52) U.S. Cl. CPC H01L 29/66742; H01L 29/0665; H01L 29/42392; H01L 29/78618; H01L 29/78696; H01L 21/0259; H01L 21/02609; H01L 21/02532; H01L 29/66545; H01L 29/66553

(57) ABSTRACT

A method includes depositing a first semiconductor layer and a second semiconductor layer over a substrate; patterning the first semiconductor layer, the second semiconductor layer, and the substrate to form a first nanostructure, a second nanostructure, and a semiconductor fin; forming a recess in the first nanostructure and the second nanostructure, the recess exposing the semiconductor fin; epitaxially growing a first layer in the recess, a first portion of the first layer being disposed along a first sidewall of the first nanostructure, a second portion of the first layer being disposed along the semiconductor fin, the first portion of the first layer comprising two sidewalls extending toward a middle of the recess, the first portion of the first layer further comprising a first surface most distal from the first sidewall and directly interposed between the two sidewalls, the first portion being physically separated from the second portion; and epitaxially growing a second layer over the first portion of the first layer and over the second portion of the first layer, the second layer physically connecting the first portion of the first layer to the second portion of the first layer.

### PRIORITY CLAIM AND CROSS-REFERENCE

This application claims the benefit of U.S. Provisional Application No. 63/224,905, filed on Jul. 23, 2021, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 14D, 14E, 14F, 14G, 15A, 15B, 15C, 15D, 16A, 16B, 16C, 16D, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, 24C, 25A, 25B, 25C, 26A, 26B, 26C, 27A, 27B, 27C, 27D, 28A, 28B, 28C, 28D, 29A, 29B, 29C, and 29D are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, semiconductor layers are formed over a substrate and patterned into multi-layer stacks disposed over semiconductor fins. The substrate may be a silicon wafer having a (110) crystallographic orientation, and the semiconductor layers formed over the substrate may follow the same (110) crystallographic orientation. Portions of the multi-layer stacks are removed (e.g., recessed), thereby forming the remaining portions into nanostructures. Some of the nanostructures will provide channel regions of field-effect transistors, and the (110) crystallographic orientation may achieve improved characteristics regarding current flow due to higher hole mobility in a <110>/(110) direction. The recesses formed in the multi-layer stacks expose upper surfaces of the substrate as well as side surfaces of the nanostructures. As a result, the bottom portions of the recesses include semiconductor material (e.g., the substrate) along a (110) plane, and sidewall portions of the recesses include semiconductor material (e.g., the side surfaces of the nanostructures) along a (111) plane. As a result of the (110) orientation, epitaxial source/drain regions may be grown in the recesses more efficiently and with a smaller volume.

Embodiments are described in a particular context, a die including nano-FETs. Various embodiments may be applied, however, to dies including other types of transistors (e.g., fin field-effect transistors (finFETs), planar transistors, or the like) in lieu of or in combination with the nano-FETs.

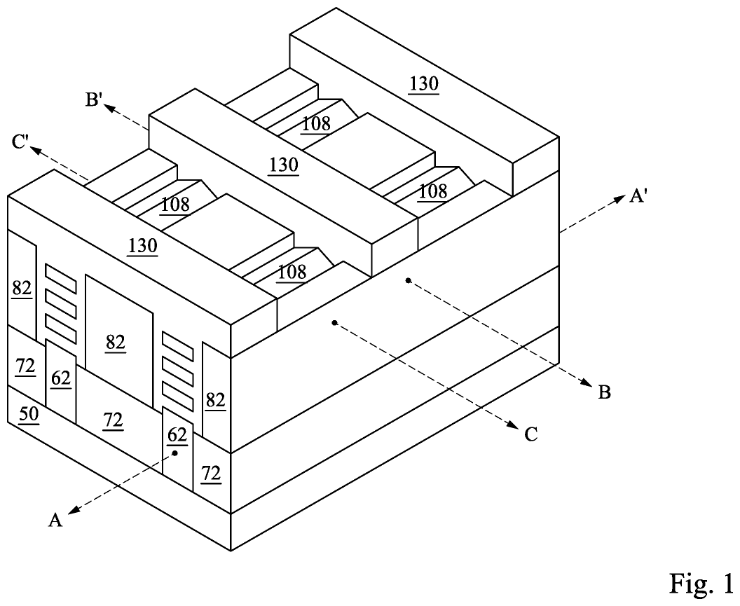

FIG. 1 illustrates an example of nano-FETs (e.g., nanowire FETs, nanosheet FETs, or the like), in accordance with some embodiments. FIG. 1 is a three-dimensional view, where some features of the nano-FETs are omitted for illustration clarity. The nano-FETs may be nanosheet field-effect transistors (NSFETs), nanowire field-effect transistors (NWFETs), gate-all-around field-effect transistors (GAAFETs), or the like.

The nano-FETs include nanostructures 66 (e.g., nanosheets, nanowires, or the like) over fins, such as semiconductor fins 62, on a substrate 50 (e.g., a semiconductor substrate), with the nanostructures 66 acting as channel regions for the nano-FETs. The nanostructures 66 may include p-type nanostructures, n-type nanostructures, or a combination thereof. Isolation regions 72, such as shallow trench isolation (STI) regions, are disposed between adjacent semiconductor fins 62, which may protrude above and from between adjacent isolation regions 72. Although the isolation regions 72 are described/illustrated as being separate from the substrate 50, as used herein, the term “substrate” may refer to the semiconductor substrate alone or a combination of the semiconductor substrate and the isolation regions. Additionally, although the bottom portions of the semiconductor fins 62 are illustrated as being separate from the substrate 50, the bottom portions of the semiconductor fins 62 may be single, continuous materials with the substrate 50. In this context, the semiconductor fins 62 refer to the portion extending above and from between the adjacent isolation regions 72.

Gate structures 130 are over top surfaces of the semiconductor fins 62 and along top surfaces, sidewalls, and bottom surfaces of the nanostructures 66. Epitaxial source/drain regions 108 are disposed on the semiconductor fins 62 at opposing sides of the gate structures 130. The epitaxial source/drain regions 108 may be shared between various semiconductor fins 62. For example, adjacent epitaxial source/drain regions 108 may be electrically connected, such as through coupling the epitaxial source/drain regions 108 with a same source/drain contact.

Insulating fins 82, also referred to as hybrid fins or dielectric fins, are disposed over the isolation regions 72, and between adjacent epitaxial source/drain regions 108. The insulating fins 82 block epitaxial growth to prevent coalescing of some of the epitaxial source/drain regions 108 during epitaxial growth. For example, the insulating fins 82 may be formed at cell boundaries to separate the epitaxial source/drain regions 108 of adjacent cells.

FIG. 1 further illustrates reference cross-sections that are used in later figures. Cross-section A-A′ is along a longitudinal axis of a semiconductor fin 62 and in a direction of, for example, a current flow between the epitaxial source/drain regions 108 of the nano-FET. Cross-section B-B′ is along a longitudinal axis of a gate structure 130 and in a direction, for example, perpendicular to a direction of current flow between the epitaxial source/drain regions 108 of a nano-FET. Cross-section C-C′ is parallel to cross-section B-B′ and extends through epitaxial source/drain regions 108 of the nano-FETs. Subsequent figures refer to these reference cross-sections for clarity.

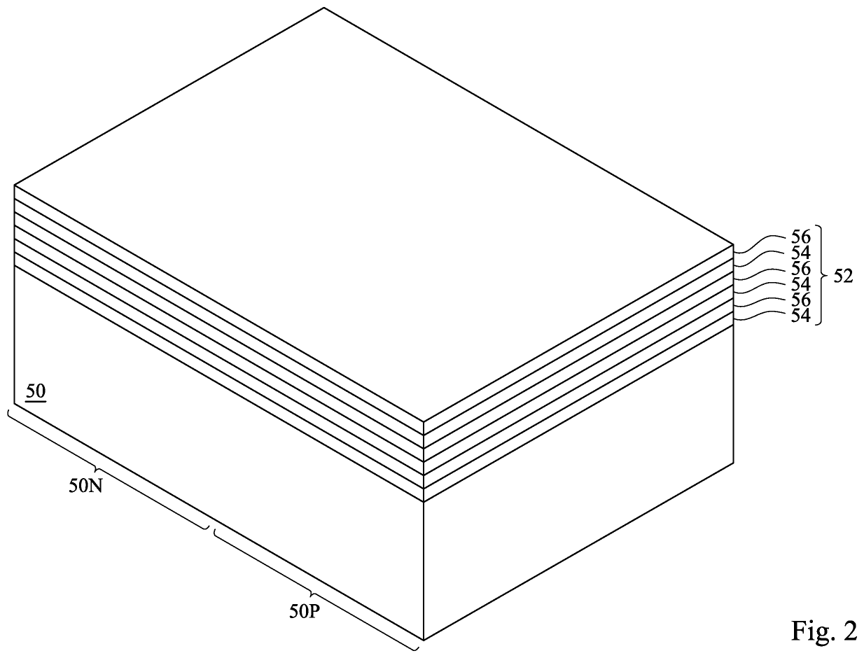

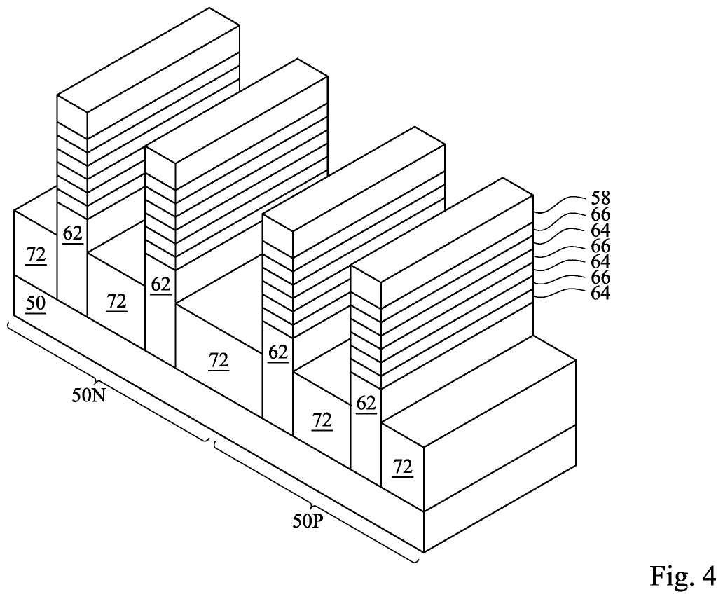

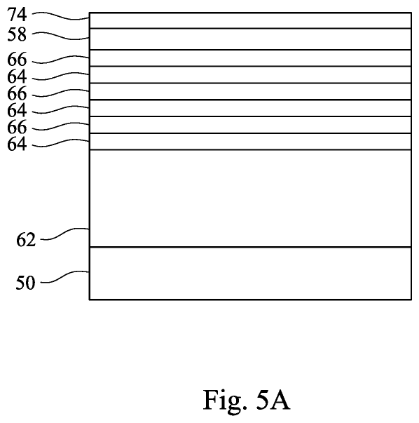

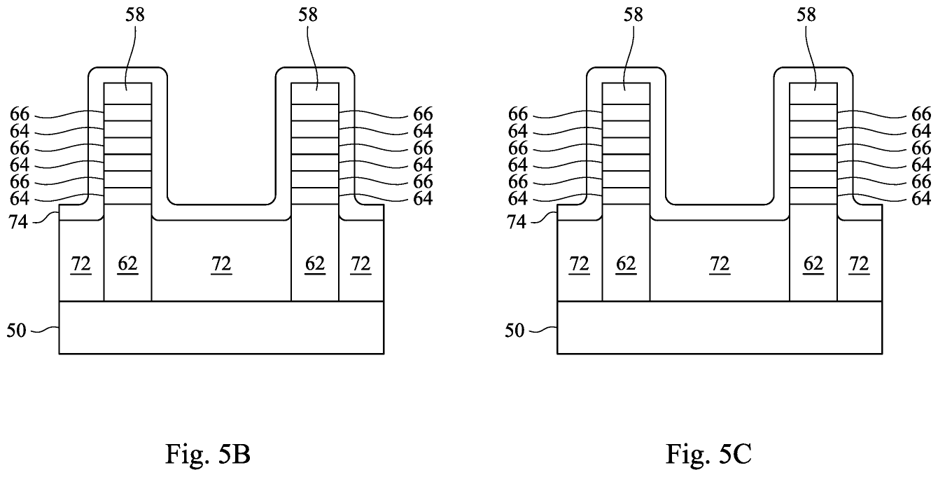

FIGS. 2-29C are views of intermediate stages in the manufacturing of nano-FETs, in accordance with some embodiments. FIGS. 2, 3, and 4 are three-dimensional views. FIGS. 5A, 6A, 7A, 8A, 9A, 10A, 11A, 12A, 13A, 14A, 14B, 14C, 14D, 14E, 15A, 15B, 16A, 16B, 17A, 18A, 19A, 20A, 21A, 22A, 23A, 24A, 25A, 26A, 27A, 27B, 28A, 28B, 29A, and 29B are cross-sectional views illustrated along a similar cross-section as reference cross-section A-A′ in FIG. 1. FIGS. 5B, 6B, 7B, 8B, 9B, 10B, 11B, 12B, 13B, 14F, 15C, 16C, 17B, 18B, 19B, 20B, 21B, 22B, 23B, 24B, 25B, 26B, 27C, 28C, and 29C are cross-sectional views illustrated along a similar cross-section as reference cross-section B-B′ in FIG. 1. FIGS. 5C, 6C, 7C, 8C, 9C, 10C, 11C, 12C, 13C, 14G, 15D, 16D, 17C, 18C, 19C, 20C, 21C, 22C, 23C, 24C, 25C, 26C, 27D, 28D, and 29D are cross-sectional views illustrated along a similar cross-section as reference cross-section C-C′ in FIG. 1.

In FIG. 2, a substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (not separately illustrated), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

The substrate 50 may be lightly doped with a p-type or an n-type impurity. An anti-punch-through (APT) implantation may be performed on an upper portion of the substrate 50 to form an APT region. During the APT implantation, impurities may be implanted in the substrate 50. The impurities may have a conductivity type opposite from a conductivity type of source/drain regions that will be subsequently formed in each of the n-type region 50N and the p-type region 50P. The APT region may extend under the source/drain regions in the nano-FETs. The APT region may be used to reduce the leakage from the source/drain regions to the substrate 50. In some embodiments, the doping concentration in the APT region is in the range of 10¹⁸ cm⁻³ to 10¹⁹ cm⁻³.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, the multi-layer stack 52 includes three layers of each of the first semiconductor layers 54 and the second semiconductor layers 56. It should be appreciated that the multi-layer stack 52 may include any number of the first semiconductor layers 54 and the second semiconductor layers 56. For example, the multi-layer stack 52 may include from one to ten layers of each of the first semiconductor layers 54 and the second semiconductor layers 56.

In the illustrated embodiment, and as will be subsequently described in greater detail, the first semiconductor layers 54 will be removed and the second semiconductor layers 56 will patterned to form channel regions for the nano-FETs in both the n-type region 50N and the p-type region 50P. The first semiconductor layers 54 are sacrificial layers (or dummy layers), which will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon. Each of the first semiconductor layers 54 (e.g., comprising silicon germanium) may be formed with a thickness of between about 5 nm and about 30 nm, and each of the second semiconductor layers 56 (e.g., comprising silicon) may be formed with a thickness of between about 5 nm and about 60 nm.

In another embodiment (not separately illustrated), the first semiconductor layers 54 will be patterned to form channel regions for nano-FETs in one region (e.g., the p-type region 50P), and the second semiconductor layers 56 will be patterned to form channel regions for nano-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without removing the second semiconductor layers 56 in the n-type region 50N, and the second semiconductor layers 56 may be removed without removing the first semiconductor layers 54 in the p-type region 50P.

As discussed above, the substrate 50 may be part of a silicon wafer having a (110) crystallographic orientation. In some embodiments, the multi-layer stack 52 (e.g., the first semiconductor layers 54 and the second semiconductor layers 56) may follow the same (110) orientation. In other embodiments not specifically illustrated, the substrate 50 may be part of a silicon wafer with a different crystallographic orientation, such as (001), while some or all of the first semiconductor layers 54 and the second semiconductor layers 56 are formed with (110) crystallographic orientations. The (110) crystallographic orientation in portions of the multi-layer stack 52 that become channel regions may provide improved device performance with a larger effective inverter current I_{Deff} through channel regions between the epitaxial source/drain regions 108 due to higher hole mobility along the <110>/(110) direction.

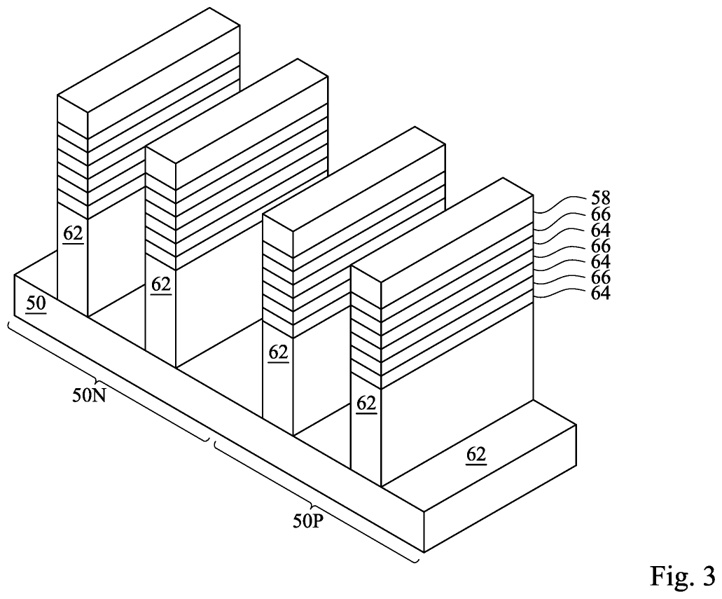

In FIG. 3, trenches are patterned in the substrate 50 and the multi-layer stack 52 to form semiconductor fins 62, nanostructures 64, and nanostructures 66. The semiconductor fins 62 are semiconductor strips patterned in the substrate 50. The nanostructures 64 and the nanostructures 66 include the remaining portions of the first semiconductor layers 54 and the second semiconductor layers 56, respectively. The trenches may be patterned by any acceptable etch process, such as a reactive ion etch (RIE), neutral beam etch (NBE), the like, or a combination thereof. The etching may be anisotropic.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as a mask 58 to pattern the semiconductor fins 62 and the nanostructures 64, 66.

In some embodiments, the semiconductor fins 62 and the nanostructures 64, 66 each have widths in a range of 8 nm to 40 nm. In the illustrated embodiment, the semiconductor fins 62 and the nanostructures 64, 66 have substantially equal widths in the n-type region 50N and the p-type region 50P. In another embodiment, the semiconductor fins 62 and the nanostructures 64, 66 in one region (e.g., the n-type region 50N) are wider or narrower than the semiconductor fins 62 and the nanostructures 64, 66 in another region (e.g., the p-type region 50P). Further, while each of the semiconductor fins 62 and the nanostructures 64, 66 are illustrated as having a consistent width throughout, in other embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

In accordance with some embodiments, some or all of the semiconductor fins 62 may be aligned in the <110>/(110) direction (e.g., formed over the (110) oriented silicon wafer). In particular, the nanostructures 64, 66 of the semiconductor fins 62 may follow the <110>/(110) direction. In addition, others of the semiconductor fins 62 may be aligned in a different crystallographic direction, such as a <110>/(100) direction. Notably, the hole mobility of the semiconductor fins 62 in the <110>/(110) direction is higher.

In FIG. 4, STI regions 72 are formed over the substrate 50 and between adjacent semiconductor fins 62. The STI regions 72 are disposed around at least a portion of the semiconductor fins 62 such that at least a portion of the nanostructures 64, 66 protrude from between adjacent STI regions 72. In the illustrated embodiment, the top surfaces of the STI regions 72 are below the top surfaces of the semiconductor fins 62. In some embodiments, the top surfaces of the STI regions 72 are above or coplanar (within process variations) with the top surfaces of the semiconductor fins 62.

The STI regions 72 may be formed by any suitable method. For example, an insulation material can be formed over the substrate 50 and the nanostructures 64, 66, and between adjacent semiconductor fins 62. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the nanostructures 64, 66. Although the STI regions 72 are each illustrated as a single layer, some embodiments may utilize multiple layers. For example, in some embodiments a liner (not separately illustrated) may first be formed along surfaces of the substrate 50, the semiconductor fins 62, and the nanostructures 64, 66. Thereafter, an insulation material, such as those previously described may be formed over the liner.

A removal process is then applied to the insulation material to remove excess insulation material over the nanostructures 64, 66. In some embodiments, a planarization process such as a chemical mechanical polish (CMP), an etch-back process, combinations thereof, or the like may be utilized. In some embodiments, the planarization process may expose the mask 58 or remove the mask 58. After the planarization process, the top surfaces of the insulation material and the mask 58 or the nanostructures 64, 66 are coplanar (within process variations). Accordingly, the top surfaces of the mask 58 (if present) or the nanostructures 64, 66 are exposed through the insulation material. In the illustrated embodiment, the mask 58 remains on the nanostructures 64, 66. The insulation material is then recessed to form the STI regions 72. The insulation material is recessed such that at least a portion of the nanostructures 64, 66 protrude from between adjacent portions of the insulation material. Further, the top surfaces of the STI regions 72 may have a flat surface as illustrated, a convex surface, a concave surface (such as dishing), or a combination thereof by applying an appropriate etch. The insulation material may be recessed using any acceptable etching process, such as one that is selective to the material of the insulation material (e.g., selectively etches the insulation material of the STI regions 72 at a faster rate than the materials of the semiconductor fins 62 and the nanostructures 64, 66). For example, an oxide removal may be performed using dilute hydrofluoric (dHF) acid as an etchant.

The process previously described is just one example of how the semiconductor fins 62 and the nanostructures 64, 66 may be formed. In some embodiments, the semiconductor fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64, 66. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 64, 66, the semiconductor fins 62, and/or the substrate 50. The wells may have a conductivity type opposite from a conductivity type of source/drain regions that will be subsequently formed in each of the n-type region 50N and the p-type region 50P. In some embodiments, a p-type well is formed in the n-type region 50N, and an n-type well is formed in the p-type region 50P. In some embodiments, a p-type well or an n-type well is formed in both the n-type region 50N and the p-type region 50P.

In embodiments with different well types, different implant steps for the n-type region 50N and the p-type region 50P may be achieved using mask (not separately illustrated) such as a photoresist. For example, a photoresist may be formed over the semiconductor fins 62, the nanostructures 64, 66, and the STI regions 72 in the n-type region 50N. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of 10¹³ cm⁻³ to 10¹⁴ cm⁻³. After the implant, the photoresist may be removed, such as by any acceptable ashing process.

Following or prior to the implanting of the p-type region 50P, a mask (not separately illustrated) such as a photoresist is formed over the semiconductor fins 62, the nanostructures 64, 66, and the STI regions 72 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of 10¹³ cm⁻³ to 10¹⁴ cm⁻³. After the implant, the photoresist may be removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the semiconductor fins 62 and/or the nanostructures 64, 66, the grown materials may be in situ doped during growth, which may obviate the implantations, although in situ and implantation doping may be used together.

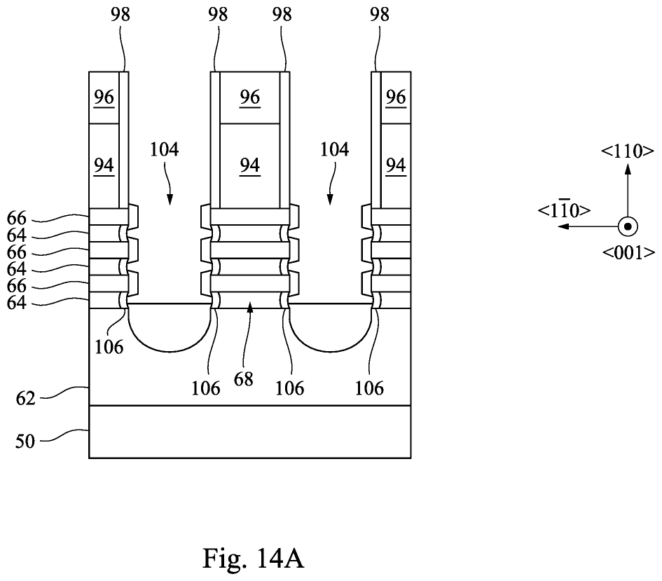

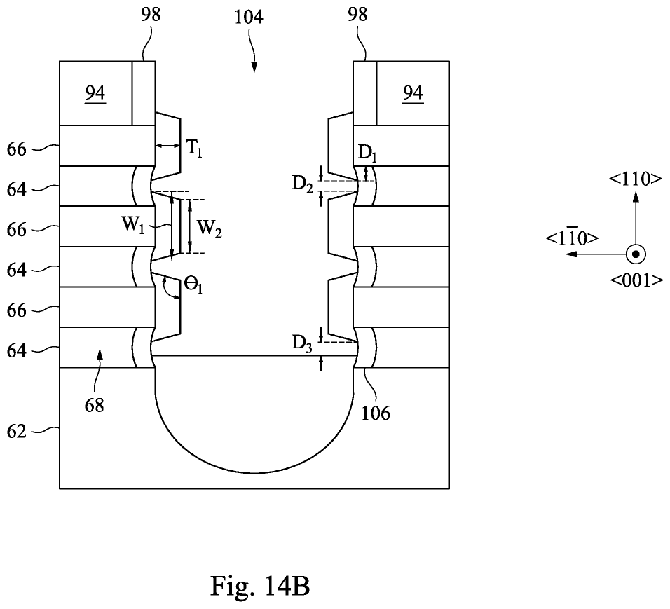

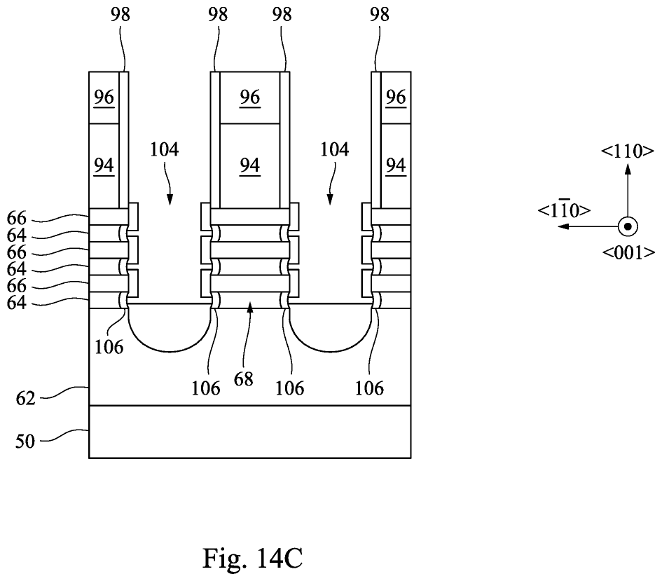

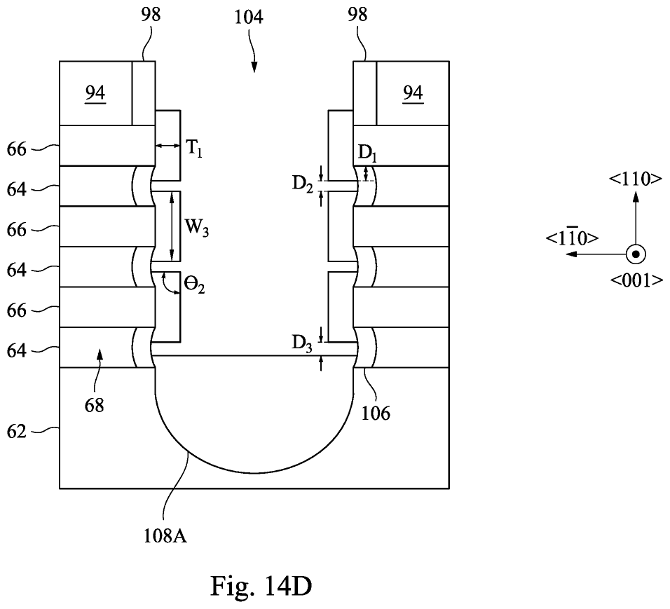

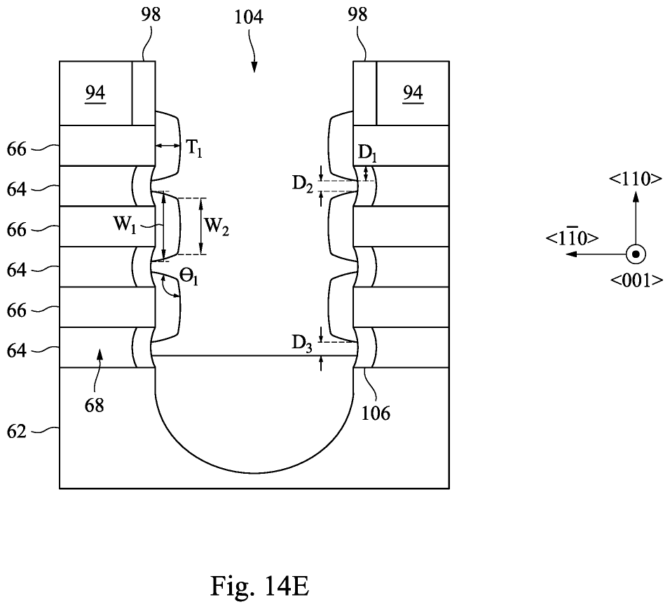

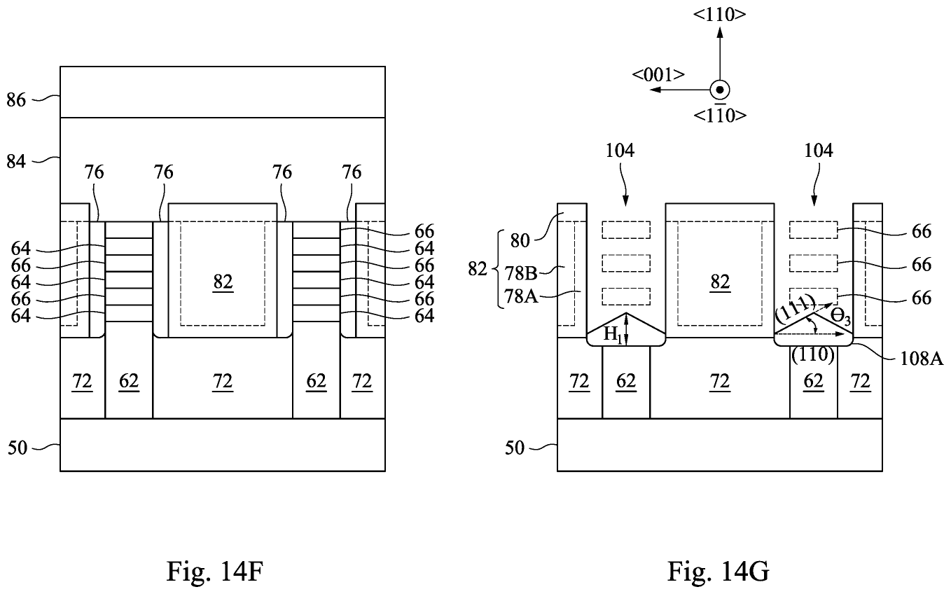

FIGS. 5A-29D illustrate various additional steps in the manufacturing of embodiment devices. FIGS. 5A-13C and 17A-23C illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are described in the text accompanying each figure. FIGS. 14A-26D and 24A-29D illustrate features in the p-type region 50P. However, in some embodiments, the structures illustrated may also be applicable to the n-type region 50N. As will be subsequently described in greater detail, insulating fins 82 will be formed between the semiconductor fins 62. Some of the figures illustrate a semiconductor fin 62 and structures formed on it. Others of the figures illustrate two semiconductor fins 62 and portions of the insulating fins 82 and the STI regions 72 that are disposed between the two semiconductor fins 62 in the respective cross-sections.

In FIGS. 5A-C, a sacrificial layer 74 is conformally formed over the mask 58, the semiconductor fins 62, the nanostructures 64, 66, and the STI regions 72. The sacrificial layer 74 may be formed of a semiconductor material (such as one selected from the candidate semiconductor materials of the substrate 50), which may be grown by a process such as vapor phase epitaxy (VPE) or molecular beam epitaxy (MBE), deposited by a process such as chemical vapor deposition (CVD) or atomic layer deposition (ALD), or the like. For example, the sacrificial layer 74 may be formed of silicon or silicon germanium.

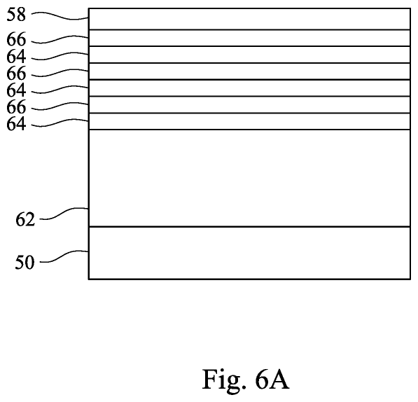

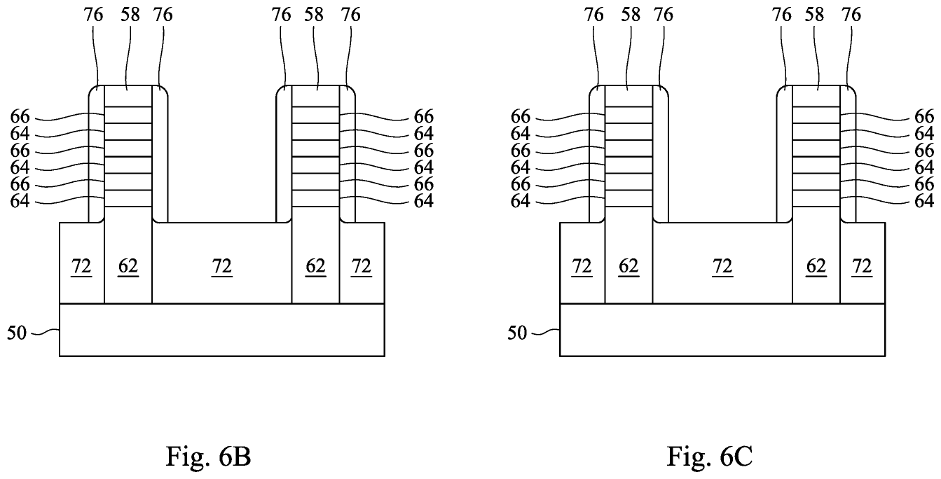

In FIGS. 6A-C, the sacrificial layer 74 is patterned to form sacrificial spacers 76 using an etching process, such as a dry etch, a wet etch, or a combination thereof. The etching process may be anisotropic. As a result of the etching process, the portions of the sacrificial layer 74 directly over the mask 58 and the nanostructures 64, 66 are removed, and the STI regions 72 between the nanostructures 64, 66 are partially exposed. The sacrificial spacers 76 are disposed over the STI regions 72 and are further disposed on the sidewalls of the mask 58, the semiconductor fins 62, and the nanostructures 64, 66.

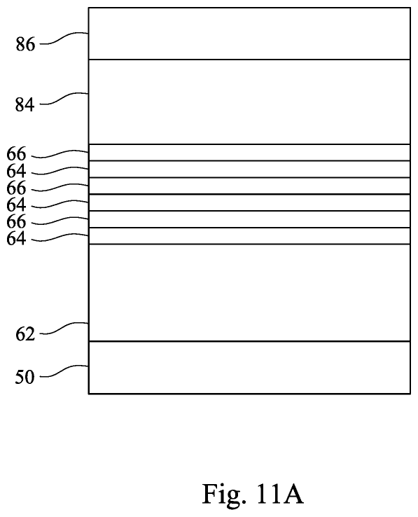

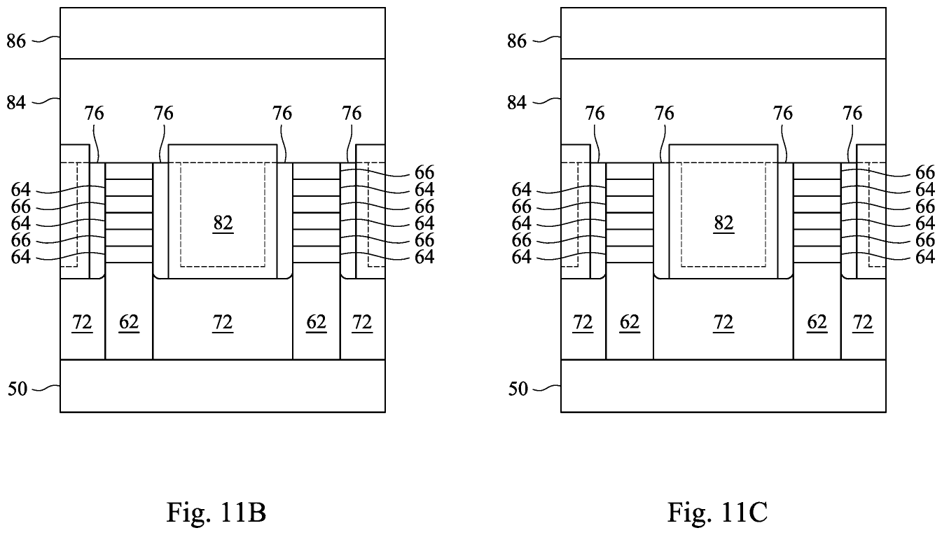

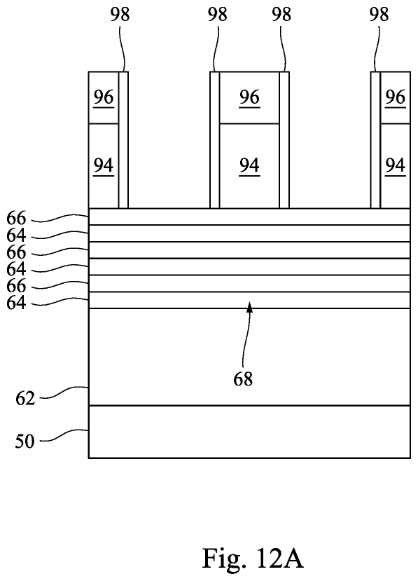

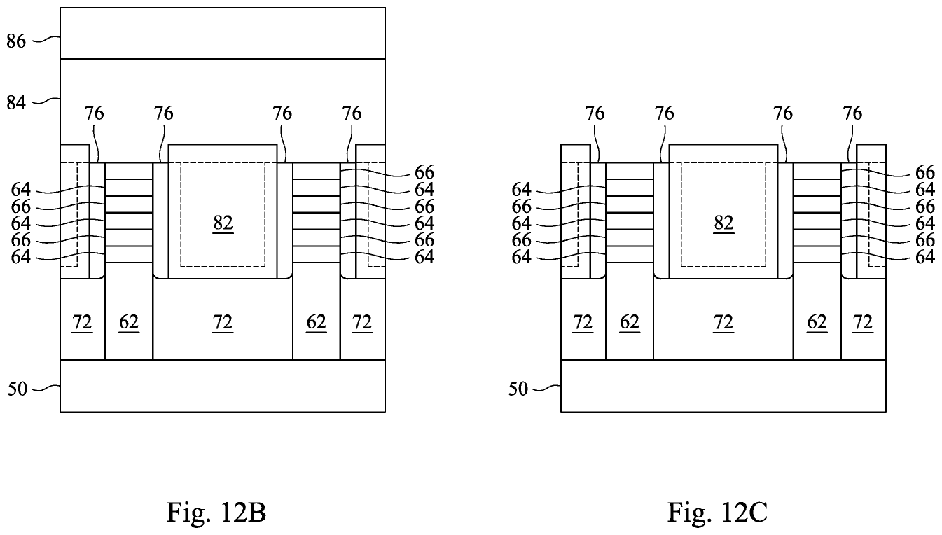

In subsequent process steps, a dummy gate layer 84 may be deposited over portions of the sacrificial spacers 76 (see below, FIGS. 11A-C), and the dummy gate layer 84 may be patterned to provide dummy gates 94 that include underlying portions of the sacrificial spacers 76 (see below, FIGS. 12A-C). These dummy gates 94 (e.g., patterned portions of the dummy gate layer 84 and portions of the sacrificial spacers 76) may then be replaced with a functional gate stack. Specifically, the sacrificial spacers 76 are used as temporary spacers during processing to delineate boundaries of insulating fins, and the sacrificial spacers 76 and the nanostructures 64 will be subsequently removed and replaced with gate structures that are wrapped around the nanostructures 66. The sacrificial spacers 76 are formed of a material that has a high etching selectivity from the etching of the material of the nanostructures 66. For example, the sacrificial spacers 76 may be formed of the same semiconductor material as the nanostructures 64 so that the sacrificial spacers 76 and the nanostructures 64 may be removed in a single process step. Alternatively, the sacrificial spacers 76 may be formed of a different material as the nanostructures 64.

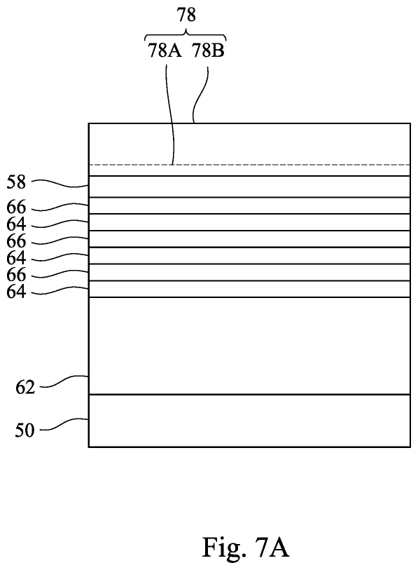

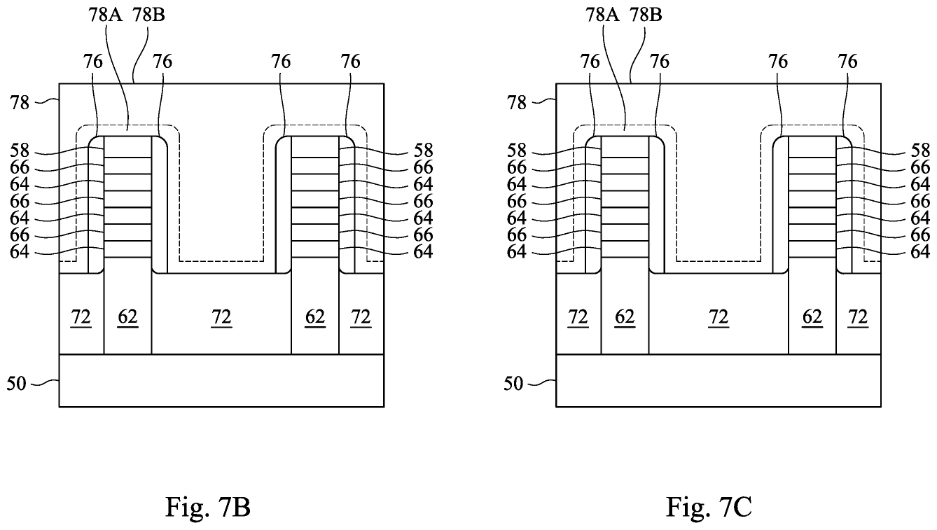

FIGS. 7A through 9C illustrate a formation of insulating fins 82 (also referred to as hybrid fins or dielectric fins) between the sacrificial spacers 76 adjacent to the semiconductor fins 62 and nanostructures 64, 66. The insulating fins 82 may insulate and physically separate subsequently formed source/drain regions (see below, FIGS. 14A-16C) from each other. For example, a major axis of the insulating fins 82 may be substantially parallel with a major axis of an adjacent semiconductor fin 62.

In FIGS. 7A-C, a liner 78A and a fill material 78B are formed over the structure. The liner 78A is conformally deposited over exposed surfaces of the STI regions 72, the masks 58, the semiconductor fins 62, the nanostructures 64, 66, and the sacrificial spacers 76 by an acceptable deposition process such as atomic layer deposition (ALD), chemical vapor deposition (CVD), physical vapor deposition (PVD), or the like. The liner 78A may be formed of one or more dielectric material(s) having a high etching selectivity from the etching of the semiconductor fins 62, the nanostructures 64, 66, and the sacrificial spacers 76, e.g. a nitride such as silicon nitride, silicon carbonitride, silicon oxycarbonitride, or the like. The liner 78A may reduce oxidation of the sacrificial spacers 76 during the subsequent formation of the fill material 78B, which may be useful for a subsequent removal of the sacrificial spacers 76.

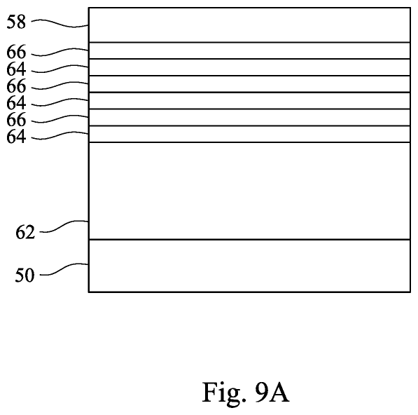

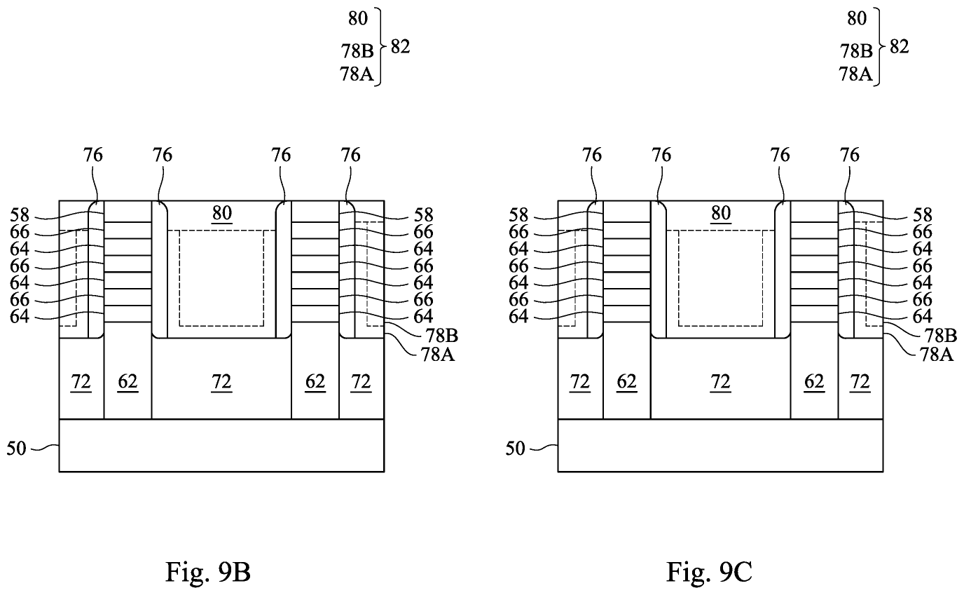

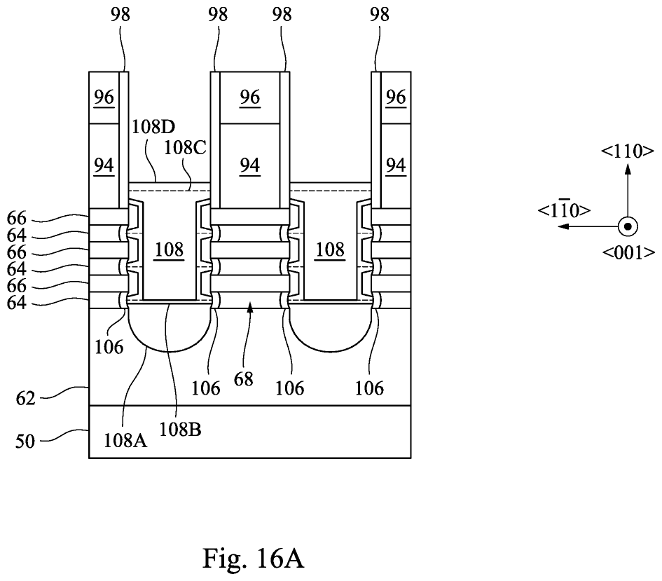

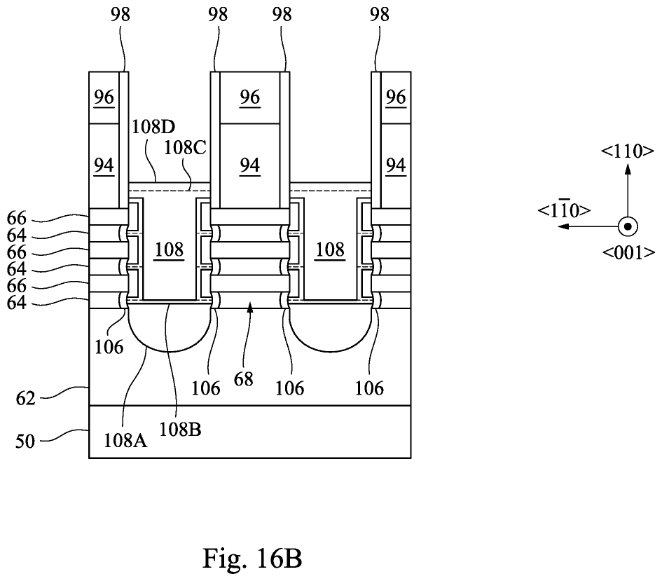

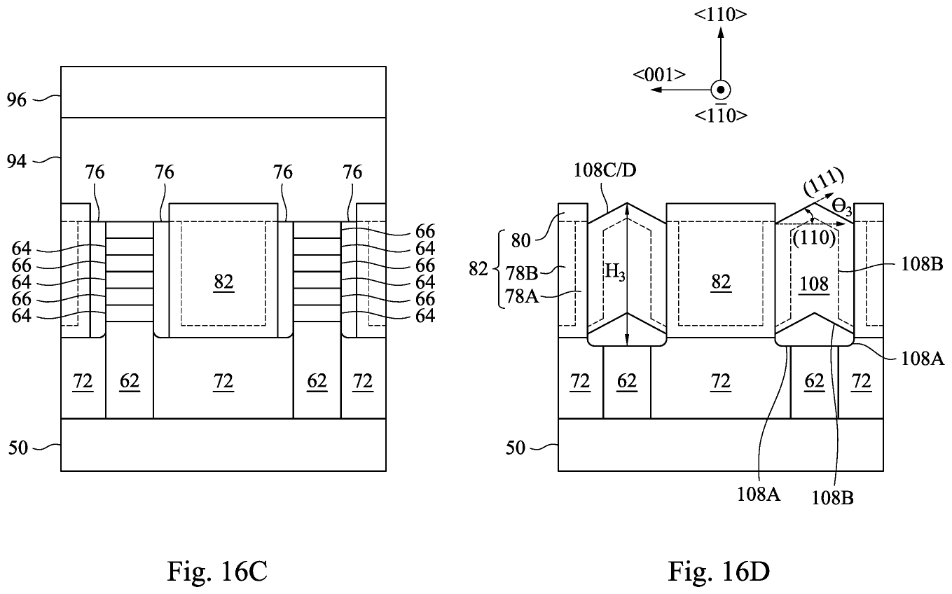

Next, a fill material 78B is formed over the liner 78A, filling the remaining area between the semiconductor fins 62 and the nanostructures 64, 66 that is not filled by the sacrificial spacers 76 or the liner 78A. The fill material 78B may form the bulk of the lower portions of the insulating fins 82 (see FIGS. 9A-C) to insulate subsequently formed source/drain regions (see FIG. 16C) from each other. The fill material 78B may be formed by an acceptable deposition process such as ALD, CVD, PVD, or the like. The fill material 78B may be formed of one or more dielectric material(s) having a high etching selectivity from the etching of the semiconductor fins 62, the nanostructures 64, 66, the sacrificial spacers 76, and the liner 78A such as an oxide such as silicon oxide, silicon oxynitride, silicon oxycarbonitride, silicon oxycarbide, the like, or combinations thereof.

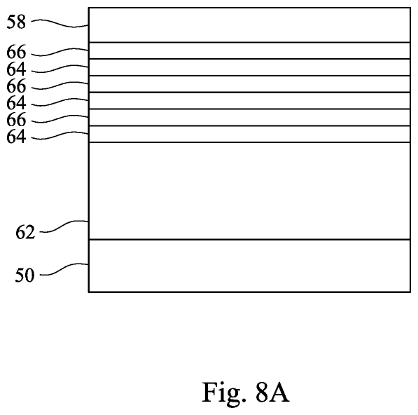

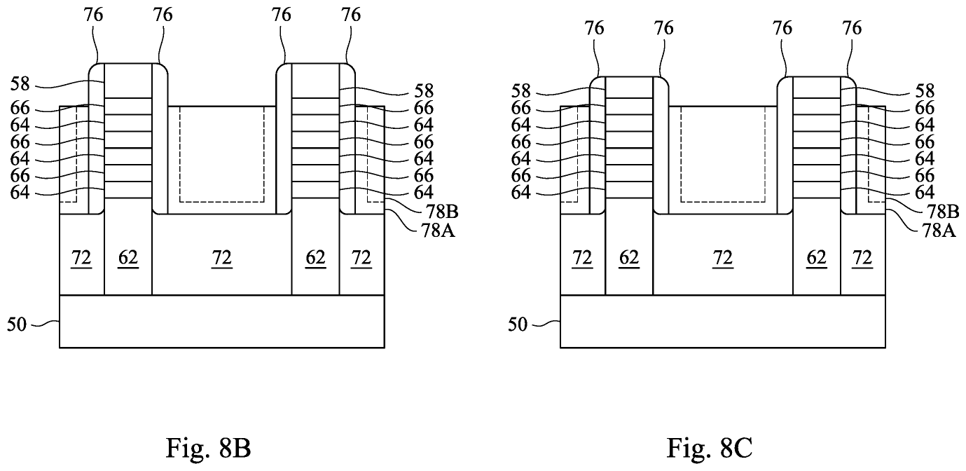

In FIGS. 8A-C, upper portions of the liner 78A and the fill material 78B above top surfaces of the masks 58 may be removed using one or more acceptable planarization and/or etching processes. The etching process may be selective to the liner 78A and to the fill material 78B (e.g., selectively etches the liner 78A and the fill material 78B at a faster rate than the sacrificial spacers 76 and/or the mask 58). After etching, top surfaces of the liner 78A and the fill material 78B may be below top surfaces of the mask 58. In other embodiments, the fill material 78 may be recessed below top surfaces of the mask 58 while the liner 78A is maintained at a same level as the mask 58.

FIGS. 9A-C illustrate the forming of a dielectric capping layer 80 on the liner 78A and the fill material 78B, thereby forming the insulating fins 82. The dielectric capping layer 80 may fill a remaining area over the liner 78A, over the fill material 78B, and between sidewalls of the mask 58. The dielectric capping layer 80 may be formed by an acceptable deposition process such as ALD, CVD, PVD, or the like. The dielectric capping layer 80 may be formed of one or more dielectric material(s) having a high etching selectivity from the etching of the semiconductor fins 62, the nanostructures 64, 66, the sacrificial spacers 76, the liner 78A, and the fill material 78B. For example, the dielectric capping layer 80 may comprise a high-k material such as hafnium oxide, zirconium oxide, zirconium aluminum oxide, hafnium aluminum oxide, hafnium silicon oxide, aluminum oxide, the like, or combinations thereof.

The dielectric capping layer 80 may be formed to initially cover the mask 58 and the nanostructures 64, 66. Subsequently, a removal process is applied to remove excess material(s) of the dielectric capping layer 80. In some embodiments, a planarization process such as a CMP, an etch-back process, combinations thereof, or the like may be utilized. The planarization process exposes the masks 58 such that top surfaces of the masks 58, the sacrificial spacers 76, and the dielectric capping layer 80 are coplanar (within process variations). In the illustrated embodiment, the masks 58 remain after the planarization process. In another embodiment, portions of or the entirety of the masks 58 may also be removed by the planarization process.

As a result, insulating fins 82 are formed between and contacting the sacrificial spacers 76. The insulating fins 82 comprise the liner 78A, the fill material 72B, and the dielectric capping layer 80. The sacrificial spacers 76 space the insulating fins 82 apart from the nanostructures 64, 66, and a size of the insulating fins 82 may be adjusted by adjusting a thickness of the sacrificial spacers 76.

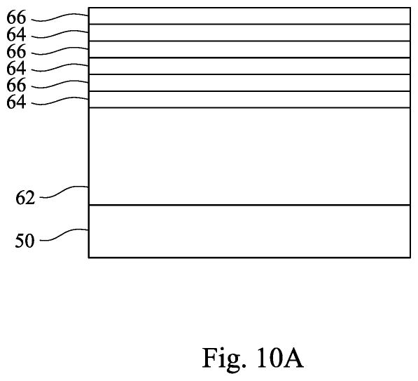

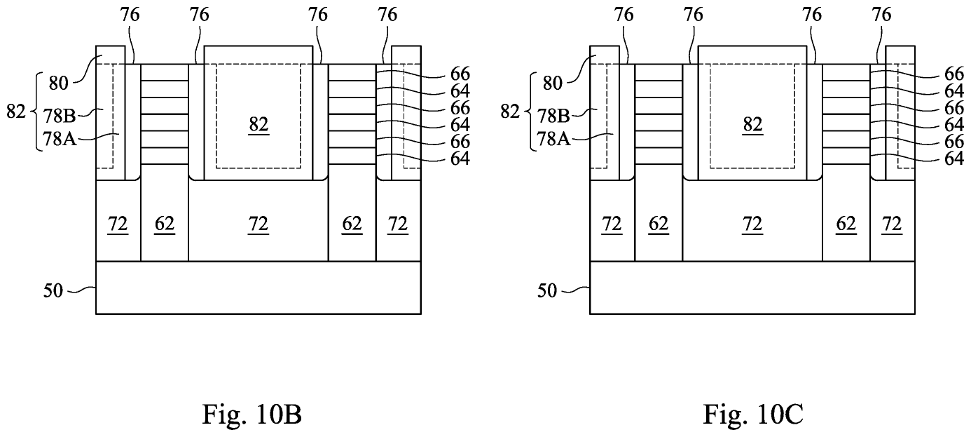

In FIGS. 10A-C, the mask 58 is removed using an etching process, for example. The etching process may be a wet etch that selective removes the mask 58 without significantly etching the insulating fins 82. The etching process may be anisotropic. Further, the etching process (or a separate, selective etching process) may also be applied to reduce a height of the sacrificial spacers 76 to a similar level (e.g., same within processing variations) as the stacked nanostructures 64, 66. After the etching process(es), a topmost surface of the stacked nanostructures 64, 66 and the sacrificial spacers 76 may be exposed and may be lower than a topmost surface of the insulating fins 82.

In FIG. 11A-C, a dummy gate layer 84 is formed on the insulating fins 82, the sacrificial spacers 76, and the nanostructures 64, 66. Because the nanostructures 64, 66 and the sacrificial spacers 76 extend lower than the insulating fins 82, the dummy gate layer 84 may be disposed along exposed sidewalls of the insulating fins 82. The dummy gate layer 84 may be deposited and then planarized, such as by a CMP. The dummy gate layer 84 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer 84 may also be formed of a semiconductor material (such as one selected from the candidate semiconductor materials of the substrate 50), which may be grown by a process such as vapor phase epitaxy (VPE) or molecular beam epitaxy (MBE), deposited by a process such as chemical vapor deposition (CVD) or atomic layer deposition (ALD), or the like. The dummy gate layer 84 may be formed of material(s) that have a high etching selectivity from the etching of insulation materials, e.g., the insulating fins 82. A mask layer 86 may be deposited over the dummy gate layer 84. The mask layer 86 may be formed of a dielectric material such as silicon nitride, silicon oxynitride, or the like. In this example, a single dummy gate layer 84 and a single mask layer 86 are formed across the n-type region 50N and the p-type region 50P.

In FIGS. 12A-C, the mask layer 86 is patterned using acceptable photolithography and etching techniques to form masks 96. The pattern of the masks 96 is then transferred to the dummy gate layer 84 by any acceptable etching technique to form dummy gates 94. The dummy gates 94 cover the top surface of the nanostructures 64, 66 that will be exposed in subsequent processing to form channel regions 68. The pattern of the masks 96 may be used to physically separate adjacent dummy gates 94. The dummy gates 94 may also have lengthwise directions substantially perpendicular (within process variations) to the lengthwise directions of the semiconductor fins 62. The masks 96 can optionally be removed after patterning, such as by any acceptable etching technique.

The sacrificial spacers 76 and the dummy gates 94 collectively extend along the portions of the nanostructures 66 that will be patterned to form channel regions 68. Subsequently formed gate structures will replace the sacrificial spacers 76 and the dummy gates 94. Forming the dummy gates 94 over the sacrificial spacers 76 allows the subsequently formed gate structures to have a greater height.

As noted above, the dummy gates 94 may be formed of a semiconductor material. In such embodiments, the nanostructures 64, the sacrificial spacers 76, and the dummy gates 94 are each formed of semiconductor materials. In some embodiments, the nanostructures 64 and the sacrificial spacers 76 are formed of a first semiconductor material (e.g., silicon germanium) and the dummy gates 94 are formed of a second semiconductor material (e.g., silicon), so that during a replacement gate process, the dummy gates 94 may be removed in a first etching step, and the nanostructures 64 and the sacrificial spacers 76 may be removed together in a second etching step. When the nanostructures 64 and the sacrificial spacers 76 are formed of silicon germanium: the nanostructures 64 and the sacrificial spacers 76 may have similar germanium concentrations, the nanostructures 64 may have a greater germanium concentration than the sacrificial spacers 76, or the sacrificial spacers 76 may have a greater germanium concentration than the nanostructures 64. In some embodiments, the nanostructures 64 are formed of a first semiconductor material (e.g., silicon germanium) and the sacrificial spacers 76 and the dummy gates 94 are formed of a second semiconductor material (e.g., silicon), so that during a replacement gate process, the sacrificial spacers 76 and the dummy gates 94 may be removed together in a first etching step, and the nanostructures 64 may be removed in a second etching step.

Gate spacers 98 are formed over the nanostructures 64, 66, and on exposed sidewalls of the masks 96 (if present) and the dummy gates 94. The gate spacers 98 may be formed by conformally depositing one or more dielectric material(s) on the dummy gates 94 and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 94 (thus forming the gate spacers 98). After etching, the gate spacers 98 can have curved sidewalls or can have straight sidewalls.

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the semiconductor fins 62 and/or the nanostructures 64, 66 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the semiconductor fins 62 and/or the nanostructures 64, 66 exposed in the n-type region 50N. The mask may then be removed. The n-type impurities may be any of the n-type impurities previously described, and the p-type impurities may be any of the p-type impurities previously described. During the implanting, the channel regions 68 remain covered by the dummy gates 94, so that the channel regions 68 remain substantially free of the impurity implanted to form the LDD regions. The LDD regions may have a concentration of impurities in the range of 10¹⁵ cm⁻³ to 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

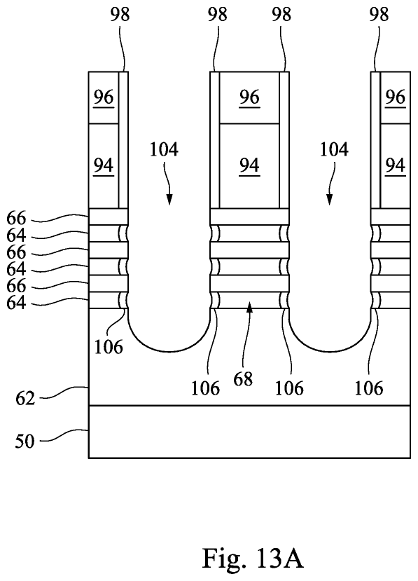

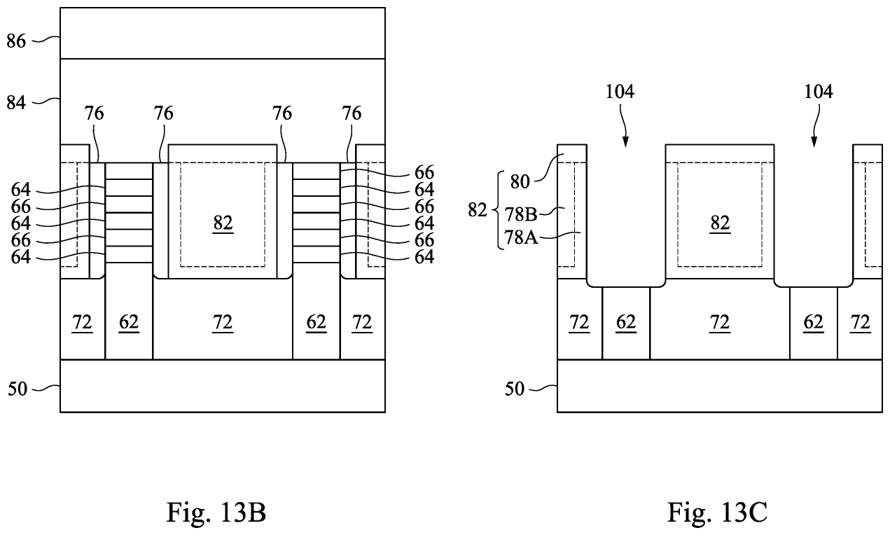

In FIGS. 13A-C, source/drain recesses 104 are formed in the nanostructures 64, 66 and the sacrificial spacers 76. In the illustrated embodiment, the source/drain recesses 104 extend through the nanostructures 64, 66 and the sacrificial spacers 76 into the semiconductor fins 62. The source/drain recesses 104 may also extend into the substrate 50. In various embodiments, the source/drain recesses 104 may extend to a top surface of the substrate 50 without etching the substrate 50; the semiconductor fins 62 may be etched such that bottom surfaces of the source/drain recesses 104 are disposed below the top surfaces of the STI regions 72; or the like. The source/drain recesses 104 may be formed by etching the nanostructures 64, 66 and the sacrificial spacers 76 using an anisotropic etching processes, such as a RIE, a NBE, or the like. The gate spacers 98 and the dummy gates 94 collectively mask portions of the semiconductor fins 62 and/or the nanostructures 64, 66 during the etching processes used to form the source/drain recesses 104. A single etch process may be used to etch each of the nanostructures 64, 66 and the sacrificial spacers 76, or multiple etch processes may be used to etch the nanostructures 64, 66 and the sacrificial spacers 76. Timed etch processes may be used to stop the etching of the source/drain recesses 104 after the source/drain recesses 104 reach a desired depth.

Optionally, inner spacers 106 are formed on the sidewalls of the nanostructures 64, e.g., those sidewalls exposed by the source/drain recesses 104. As will be subsequently described in greater detail, source/drain regions will be subsequently formed in the source/drain recesses 104, and the nanostructures 64 will be subsequently replaced with corresponding gate structures. The inner spacers 106 act as isolation features between the subsequently formed source/drain regions and the subsequently formed gate structures. Further, the inner spacers 106 may be used to substantially prevent damage to the subsequently formed source/drain regions by subsequent etching processes, such as etching processes used to subsequently remove the nanostructures 64.

As an example to form the inner spacers 106, the source/drain recesses 104 can be laterally expanded. Specifically, portions of the sidewalls of the nanostructures 64 exposed by the source/drain recesses 104 may be recessed. Although sidewalls of the nanostructures 64 are illustrated as being concave, the sidewalls may be straight or convex. The sidewalls may be recessed by any acceptable etching process, such as one that is selective to the nanostructures 64 (e.g., selectively etches the materials of the nanostructures 64 at a faster rate than the material of the nanostructures 66). The etching may be isotropic. For example, when the nanostructures 66 are formed of silicon and the nanostructures 64 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 104 and recess the sidewalls of the nanostructures 64. The inner spacers 106 are then formed on the recessed sidewalls of the nanostructures 64. The inner spacers 106 can be formed by conformally forming an insulating material and subsequently etching the insulating material. The insulating material may be silicon nitride or silicon oxynitride, although any suitable material, such as a low-k dielectric material, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 106 are illustrated as being recessed with respect to the sidewalls of the gate spacers 98, the outer sidewalls of the inner spacers 106 may extend beyond or be flush with the sidewalls of the gate spacers 98. In other words, the inner spacers 106 may partially fill, completely fill, or overfill the sidewall recesses. Moreover, although the inner sidewalls of the inner spacers 106 are illustrated as being concave, the sidewalls of the inner spacers 106 may be straight or convex.

In FIGS. 14A-16D, epitaxial source/drain regions 108 are formed in the source/drain recesses 104. The epitaxial source/drain regions 108 are formed in the source/drain recesses 104 such that each dummy gate 94 (and corresponding channel region 68) is disposed between respective adjacent pairs of the epitaxial source/drain regions 108. In some embodiments, the gate spacers 98 and the inner spacers 106 are used to separate the epitaxial source/drain regions 108 from, respectively, the dummy gates 94 and the nanostructures 64 by an appropriate lateral distance so that the epitaxial source/drain regions 108 do not short out with subsequently formed gates of the resulting nano-FETs. A material of the epitaxial source/drain regions 108 may be selected to exert stress in the respective channel regions 68, thereby improving performance.

The epitaxial source/drain regions 108 in the p-type region 50P may be formed by masking the n-type region 50N. Then, the epitaxial source/drain regions 108 in the p-type region 50P are epitaxially grown in the source/drain recesses 104 in the p-type region 50P. The epitaxial source/drain regions 108 may include any acceptable material appropriate for p-type devices. For example, if the nanostructures 66 are silicon, the epitaxial source/drain regions 108 in the p-type region 50P may include materials exerting a compressive strain on the channel regions 68, such as silicon germanium, boron doped silicon germanium, silicon germanium phosphide, germanium, germanium tin, boron doped silicon, the like, or combinations thereof. The epitaxial source/drain regions 108 in the p-type region 50P may be referred to as “p-type source/drain regions.” The epitaxial source/drain regions 108 in the p-type region 50P may have surfaces raised from respective surfaces of the semiconductor fins 62 and the nanostructures 64, 66, and may have facets.

The epitaxial source/drain regions 108 in the n-type region 50N may be formed by masking the p-type region 50P. Then, the epitaxial source/drain regions 108 in the n-type region 50N are epitaxially grown in the source/drain recesses 104 in the n-type region 50N. The epitaxial source/drain regions 108 may include any acceptable material appropriate for n-type devices. For example, if the nanostructures 66 are silicon, the epitaxial source/drain regions 108 in the n-type region 50N may include materials exerting a tensile strain on the channel regions 68, such as silicon, silicon carbide, phosphorous doped silicon carbide, silicon arsenide, silicon phosphide, the like, or combinations thereof. The epitaxial source/drain regions 108 in the n-type region 50N may be referred to as “n-type source/drain regions.” The epitaxial source/drain regions 108 in the n-type region 50N may have surfaces raised from respective surfaces of the semiconductor fins 62 and the nanostructures 64, 66, and may have facets.

The epitaxial source/drain regions 108, the nanostructures 64, 66, and/or the semiconductor fins 62 may be implanted with impurities to form source/drain regions, similar to the process previously described for forming LDD regions, followed by an anneal. The epitaxial source/drain regions 108 may have an impurity concentration in the range of 10¹⁹ cm⁻³ to 10²¹ cm⁻³. The n-type and/or p-type impurities for source/drain regions may be any of the impurities previously described. In some embodiments, the epitaxial source/drain regions 108 may be in situ doped during growth.

In accordance with some embodiments, the epitaxial source/drain regions 108 in the p-type region 50P (e.g., for PMOS devices) may include one or more semiconductor material layers. For example, the epitaxial source/drain regions 108 may each include a liner layer 108A, a merging layer 108B, a main layer 108C, and a finishing layer 108D (or more generally, a first semiconductor material layer, a second semiconductor material layer, a third semiconductor material layer, and a fourth semiconductor material layer). Any number of semiconductor material layers may be used for the epitaxial source/drain regions 108, such as more or less than the semiconductor material layers listed above. Each of the liner layer 108A, the merging layer 108B, the main layer 108C, and the finishing layer 108D may be formed of different semiconductor materials and may be doped to different impurity concentrations. In some embodiments, the liner layer 108A may have a lesser concentration of impurities than each of the merging layer 108B and the main layer 108C, and the finishing layer 108D may have a greater concentration of impurities than the liner layer 108A and a lesser concentration of impurities than the merging layer 108B and/or the main layer 108C. In embodiments in which the epitaxial source/drain regions include four semiconductor material layers, the liner layers 108A may be grown in the source/drain recesses 104, the merging layers 108B may be grown on the liner layers 108A, the main layers 108C may be grown on the merging layers 108B, and the finishing layers 108D may be grown on the main layers 108C.

In FIGS. 14A-G, the liner layer 108A (e.g., a liner material of the epitaxial source/drain regions 108) is formed in the source/drain recesses 104 along exposed surfaces of the nanostructures 66 and the substrate 50 (e.g., the semiconductor fins 62). In addition, the liner layer 108A may extend over and partially along the inner spacers 106 and the gate spacers 98. The liner layer 108A may be epitaxially grown using, for example, CVD and comprising boron-doped silicon or boron-doped silicon germanium. For example, the liner layer 108A may have a germanium concentration of up to about 25% and a boron concentration of between about 5×10¹⁹ cm⁻³ and about 10²¹ cm⁻³.

As illustrated, the liner layer 108A may form in discrete portions on each exposed surface of the nanostructures 66 and of the semiconductor fins 62. On a (110) oriented wafer, the liner layer 108A forms over sidewalls of the nanostructures 66 (e.g., along sidewalls of the source/drain recesses 104) in the [11̅0] direction and over the semiconductor fins 62 (e.g., along bottoms of the source/drain recesses 104) in the direction. The discrete portions may have trapezoidal shapes (see FIGS. 14A, 14B, and 14E) and/or rectangular shapes (see FIGS. 14C-D). The trapezoidal/rectangular shapes facilitate faster epitaxial growth than various other shapes as well as facilitate greater epitaxial growth extending over the inner spacers 106. In particular, the liner layer 108A has a low to zero deposition rate on the inner spacers 106 (e.g., as compared to on the nanostructures 66). However, the trapezoidal/rectangular shape allows the liner layer 108A to extend farther laterally over the inner spacers 106.

Although not always specifically illustrated in the figures, the discrete portions of the liner layer 108A may have curved or wavy sidewalls due to forming along curved or wavy surfaces of the source/drain recesses 104 (e.g., sidewalls of the nanostructures 66 and the inner spacers 106 as shown in FIGS. 14A-E and surfaces of the semiconductor fins 62 as shown in FIG. 14G). Sidewalls of the discrete portions not directly adjacent to the sidewalls of the source/drain recesses 104 may also have curved or wavy shapes due to process variations during epitaxial growth (see, e.g., FIG. 14E). In addition, while the discrete portions are illustrated with trapezoidal and/or rectangular shapes with three sidewalls not directly adjacent to sidewalls of the source/drain recesses 104 (e.g., the nanostructures 66 and the inner spacers 106), the discrete portions may have other shapes with more than three such sidewalls.

Referring to FIG. 14B, each discrete portion of the liner layer 108A may have a trapezoidal shape such that a surface most distal from the nanostructure 66 may be normal to a major plane of the substrate 50. As such, the discrete portions of the liner layer 108A may each have a thickness T₁ extending outward from the nanostructures 66 of between about 2 nm and about 6 nm. A width W₁ of the liner layer 108A proximal to and along the nanostructures 66 is greater than or about equal to the thickness of the nanostructures 66, such as between about 7 nm and about 13 nm. A width W₂ of the liner layer 108A distal from the nanostructures 66 may be between about 4 nm and about 10 nm. In addition, each corner of the liner layer 108A distal from the nanostructures 66 may have an angle θ₁ of between about 70° and about 130°, such as greater than about 90°.

Each discrete portion of the liner layer 108A may extend over a corresponding one of the inner spacers 106 by a distance D₁ that is less than the thickness of the nanostructures 64 and greater than about 2 nm. As a result, adjacent discrete portions of the liner layer 108A may be separated from one another by a distance D2 that is also less than the thickness of the nanostructures 64, such as less than about 2 nm. In addition, a discrete portion adjacent to a portion of the liner layer 108A formed on the semiconductor fin 62 may be separated by a distance D3 that is also less than the thickness of the nanostructures 64, such as less than about 2 nm.

Referring to FIGS. 14C-D, as discussed above, some or all of the discrete portions of the liner layer 108A adjacent to the nanostructures 66 may have rectangular shapes. For example, each corner of the liner layer 108A distal from the nanostructures 66 may have an angle θ₂ of about 90°. As such, the liner layer 108A may have a width W₃ (or an average width W₃ if not a perfect rectangle) that is greater than or about equal to the thickness of the nanostructures 66, such as between about 7 nm and about 13 nm.

FIG. 14E illustrates an exemplary depiction of the liner layer 108A being formed with curved or wavy surfaces. Note that the depicted discrete portions have trapezoidal shapes; however, sidewall of discrete portions having rectangular shapes may also exhibit similar curved or wavy surfaces. In some embodiments, some of the discrete portions of the liner layer 108A may have trapezoidal shapes with curved or wavy surfaces and sidewalls, while others of the discrete portions of the liner layer 108A may have rectangular shapes with curved or wavy surfaces and sidewalls.

Referring to FIGS. 14F-G, in a different cross-section (e.g., FIG. 14G) the discrete portions of the liner layer 108A formed on the semiconductor fins 62 may have a triangular shape due to forming on a (110) oriented wafer. The nanostructures 66 in FIG. 14F are illustrated with dotted outlines to indicate that the nanostructures 66 are not within this cross-sectional view. Upper surfaces of those portions of the liner layer 108A form along the {111} planes. The upper surfaces may, therefore, be angled from the (110) plane by an angle θ₃ being between about 30° and about 50°, such as about 35.3°. The (110) orientation of the wafer (e.g., the substrate 50 and the semiconductor fins 62) causes the angle θ₃ to be less than, for example, an angle of about 54.7°, which may be expected for a wafer having a (001) orientation. In addition, the liner layer 108A may have a height H₁ from the semiconductor fins 62 of between about 4 nm and about 8 nm. In some embodiments, an etching process, such as a vapor wet etching, may proceed during or after epitaxial growth in the formation of the liner layer 108A. As such, exposed surfaces of the liner layer 108A, such as the upper surfaces discussed above, may be facets of the crystal lattice of the epitaxial material of the liner layer 108A.

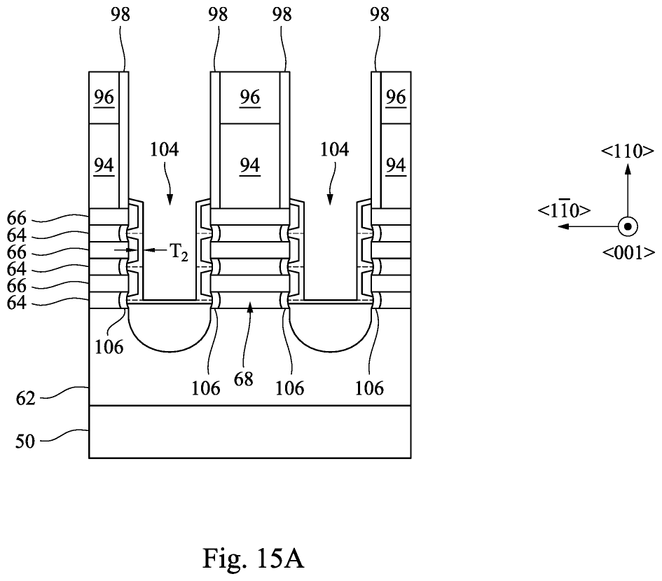

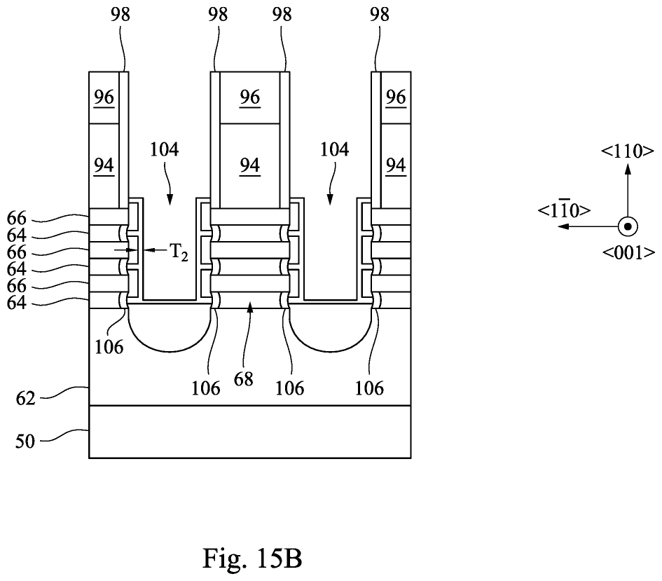

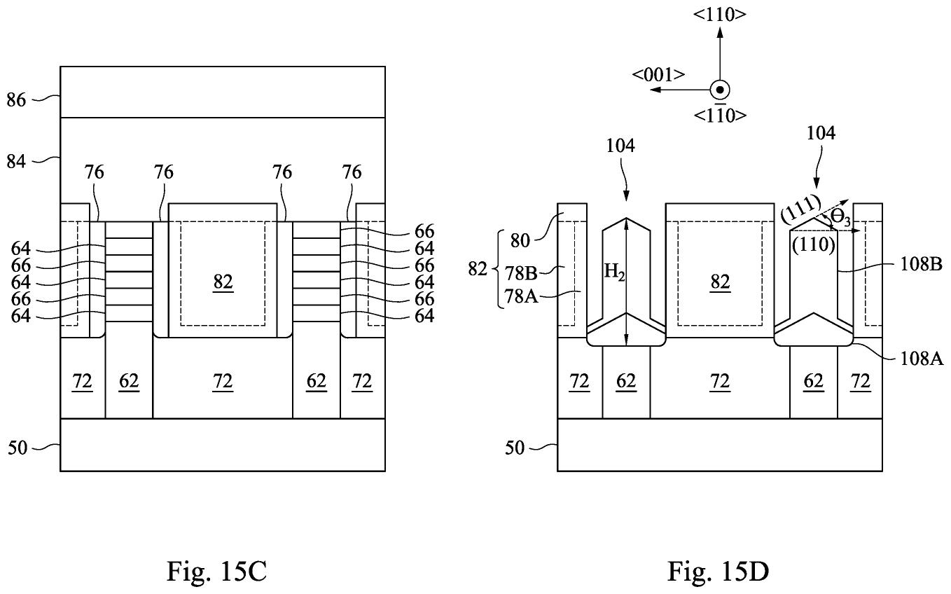

In FIGS. 15A-D, the merging layer 108B (e.g., a merging material of the epitaxial source/drain regions 108) is formed over the liner layer 108A. The merging layer 108B may be epitaxially grown using, for example, CVD and comprising boron-doped silicon germanium. For example, the merging layer 108B may have a germanium concentration being greater than a germanium concentration of the liner layer 108A, such as being greater than or equal to about 25% and a boron concentration of greater than about 5×10²⁰ cm⁻³.

As illustrated, adjacent portions of the merging layer 108B formed over the discrete portions of the liner layer 108A begin to merge with one another. In addition, some of those portions of the merging layer 108B will merge with a portion of the merging layer 108B formed on the portion of the liner layer 108A directly on the semiconductor fin 62. Although FIGS. 15A-B show this phenomenon with respect to trapezoidal shapes of the liner layer 108A, the merging would also occur for rectangular shapes of the liner layer 108A (see FIGS. 14C-D). The trapezoidal and/or rectangular shapes provide greater lateral growth of the discrete portions of the liner layer 108A, which ensures that the discrete portions will be merged during formation of the merging layer 108B. As a result, the illustrated merged profile may be FinFET-like. In addition, regions at or near seams of the merging will have fewer and smaller crystallographic fault lines. The merging layer 108B may be formed to a thickness T₂ over the liner layer 108A (e.g., portions distal from the nanostructures 64, 66) of between about 2 nm and about 5 nm.

Referring to FIG. 15D, in this cross-section the merging layer 108B may form over the liner layer 108A such that the triangular shape of upper surfaces is continued. Upper surfaces of those portions of the merging layer 108B form along the {111} planes. The upper surfaces may, therefore, be angled from the (110) plane by the angle θ₃ being between about 30° and about 50°, such as about 35.3° (e.g., similarly as with the upper surfaces of the liner layer 108A). As discussed above, the (110) orientation of the wafer (e.g., the substrate 50 and the semiconductor fins 62) causes the angle θ₃ to be less than, for example, an angle of about 54.7°, which may be expected for a wafer having a (001) orientation. In addition, the merging layer 108B and the liner layer 108A may combine to have a height H₂ from the semiconductor fins 62 of between about 40 nm and about 60 nm. In some embodiments, an etching process, such as a vapor wet etching, may proceed during or after epitaxial growth in the formation of the merging layer 108B. As such, exposed surfaces of the merging layer 108B, such as the upper surfaces discussed above, may be facets of the crystal lattice of the epitaxial material of the merging layer 108B.

In FIGS. 16A-D, the main layer 108C and the finishing layer 108D (e.g., a main material and a finishing material, respectively, of the epitaxial source/drain regions 108) are formed over the merging layer 108B. The main layer 108C and the finishing layer 108D may each be epitaxially grown using, for example, CVD and comprising boron-doped silicon germanium. The main layer 108C may include one or more layers of boron-doped silicon germanium having varying concentrations of the elements. In some embodiments, the main layer 108C includes a continuation of the merging layer 108B (e.g., having the same concentrations of the elements) to the extent the main layer 108C merges with itself across a lateral width of the source/drain recess 104. In other embodiments, the main layer 108C may have a germanium concentration greater than that of the merging layer 108B, such as greater than about 35%, and a boron concentration of greater than about 5×10²⁰ cm⁻³. In either of those embodiments, the finishing layer 108D may have a germanium concentration greater than that of the liner layer 108A (if any) and lesser than that of the merging layer 108B. Because the merging layer 108B has already merged the discrete portions of the liner layer 108A (e.g., due to the discrete portions of the liner layer 108A reaching closer to one another due to increased lateral growth), the main layer 108C formation over the merging layer 108B is improved. In particular, the merging layer 108B is more effective at merging the discrete portions than the main layer 108C would be.

As illustrated, the epitaxial source/drain regions 108 (e.g., the liner layer 108A, the merging layer 108B, the main layer 108C, and the finishing layer 108D) extend entirely across lateral dimensions of the source/drain recesses 104 in multiple cross-sections. For example, the epitaxial source/drain regions 108 extend from the nanostructures 66 on a first side of the source/drain recesses 104 to the nanostructures 66 on an opposing second side of the source/drain recesses 104. Similarly, the epitaxial source/drain regions 108 extend from the insulating fins 82 on a third side of the source/drain recesses 104 to the insulating fins 82 on an opposing fourth side of the source/drain recesses 104.

Referring to FIG. 16D, the main layer 108C and the finishing layer 108D may form over the merging layer 108B such that the triangular shape of upper surfaces is continued. Upper surfaces of those portions of the main layer 108C and/or the finishing layer 108D form along the {111} planes. The upper surfaces may, therefore, be angled from the (110) plane by the angle θ₃ being between about 30° and about 50°, such as about 35.3° (e.g., similarly as with the upper surfaces of the liner layer 108A and the merging layer 108B). In some embodiments, an etching process, such as a vapor wet etching, may proceed during or after epitaxial growth in the formation of the main layer 108C and/or the finishing layer 108D. As such, exposed surfaces of the main layer 108C and/or the finishing layer 108D, such as the upper surfaces discussed above, may be facets of the crystal lattice of the epitaxial material of those layers.

As discussed above, the (110) orientation of the wafer (e.g., the substrate 50 and the semiconductor fins 62) causes the angle θ₃ to be less than, for example, an angle of about 54.7°, which may be expected for a wafer having a (001) orientation. In addition, the epitaxial source/drain region 108 may have a height H₃ from the semiconductor fins 62 of between about 45 nm and about 65 nm. As a result, the epitaxial source/drain regions 108 formed over the (110) oriented wafer have a smaller volume. The smaller volume contributes to less gate-to-drain capacitance CGS and lower resistor-capacitor delay (RC delay), thereby improving performance of the device.

The epitaxial source/drain regions 108 in the n-type region 50N (e.g., for NMOS devices) may be formed similarly or differently from the epitaxial source/drain regions 108 in the p-type region 50P as described above. For example, the epitaxial source/drain regions 108 in the n-type region 50N may similarly include a plurality of epitaxially grown layers comprising, however, different materials. Any suitable materials and processes may be used.

As a result of the epitaxy processes used to form the epitaxial source/drain regions 108, the upper facets (or upper surfaces) of the epitaxial source/drain regions expand laterally outward beyond sidewalls of the semiconductor fins 62 and the nanostructures 64, 66. However, the insulating fins 82 block the lateral epitaxial growth. Therefore, adjacent epitaxial source/drain regions 108 remain separated after the epitaxy process is completed. The epitaxial source/drain regions 108 contact the sidewalls of the insulating fins 82. In the illustrated embodiments, the epitaxial source/drain regions 108 are grown so that the upper facets of the epitaxial source/drain regions 108 reach a point that is about the same level as the top surfaces of the insulating fins 82. In various embodiments, the upper facets of the epitaxial source/drain regions 108 are disposed entirely above the top surfaces of the insulating fins 82; the upper facets of the epitaxial source/drain regions 108 are disposed entirely below the top surfaces of the insulating fins 82; the upper facets of the epitaxial source/drain regions 108 have portions disposed above and below the top surfaces of the insulating fins 82; or combinations thereof.

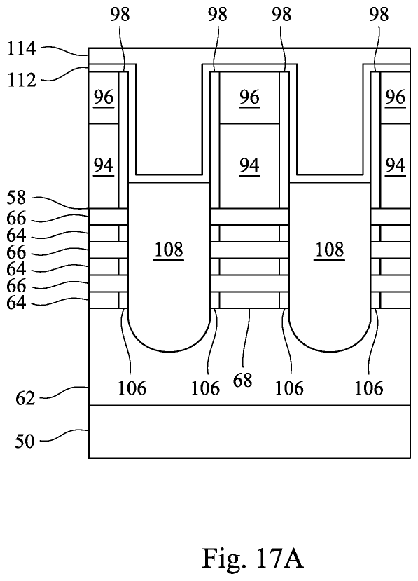

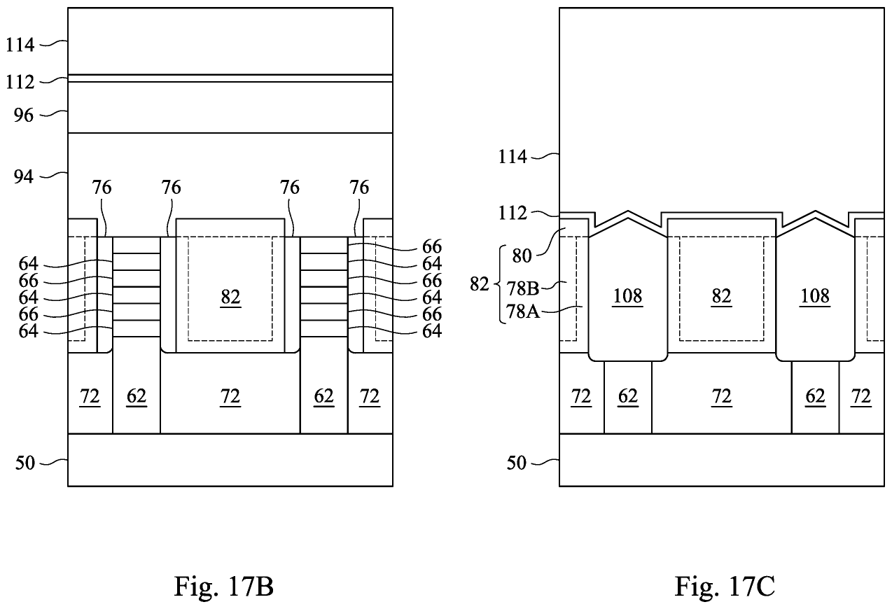

In FIGS. 17A-C, a first inter-layer dielectric (ILD) 114 is deposited over the epitaxial source/drain regions 108, the gate spacers 98, the masks 96 (if present) or the dummy gates 94. The first ILD 114 may be formed of a dielectric material, which may be deposited by any suitable method, such as CVD, PECVD, FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 112 is formed between the first ILD 114 and the epitaxial source/drain regions 108, the gate spacers 98, and the masks 96 (if present) or the dummy gates 94. The CESL 112 may be formed of a dielectric material, such as silicon nitride, silicon oxide, silicon oxynitride, or the like, having a high etching selectivity from the etching of the first ILD 114. The CESL 112 may be formed by any suitable method, such as CVD, ALD, or the like.

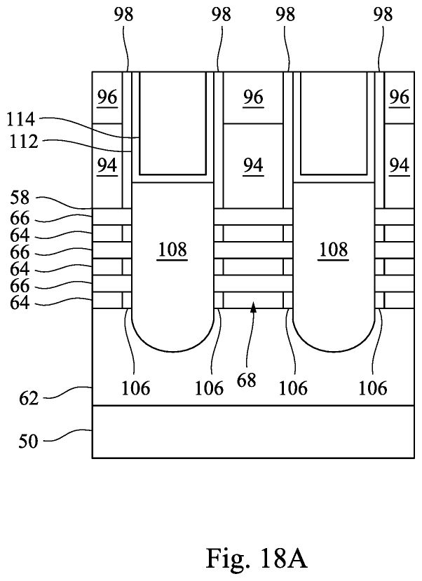

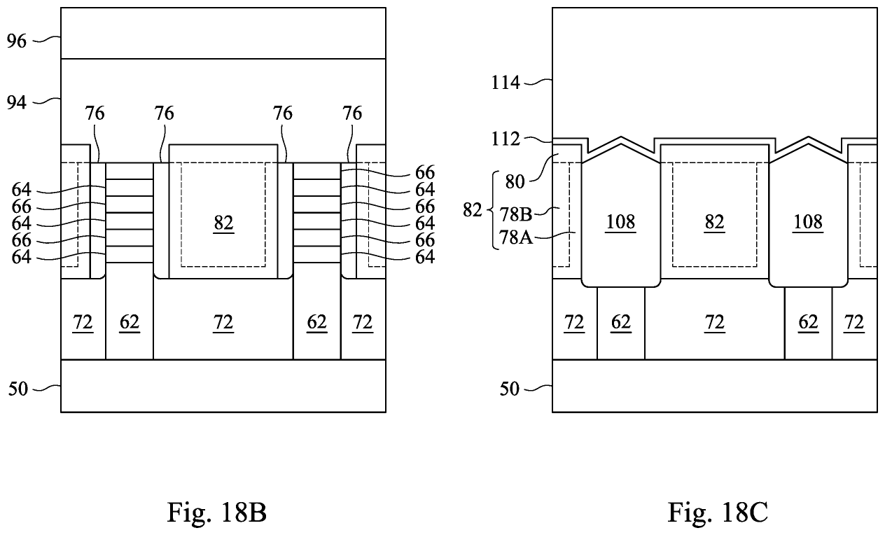

In FIGS. 18A-C, a removal process is performed to level the top surfaces of the first ILD 114 with the top surfaces of the masks 96 (if present) or the dummy gates 94. In some embodiments, a planarization process such as a chemical mechanical polish (CMP), an etch-back process, combinations thereof, or the like may be utilized. The planarization process may also remove the masks 96 on the dummy gates 94, and portions of the gate spacers 98 along sidewalls of the masks 96. After the planarization process, the top surfaces of the gate spacers 98, the first ILD 114, the CESL 112, and the masks 96 (if present) or the dummy gates 94 are coplanar (within process variations). Accordingly, the top surfaces of the masks 96 (if present) or the dummy gates 94 are exposed through the first ILD 114. In the illustrated embodiments, the masks 96 remain, and the planarization process levels the top surfaces of the first ILD 114 with the top surfaces of the masks 96.

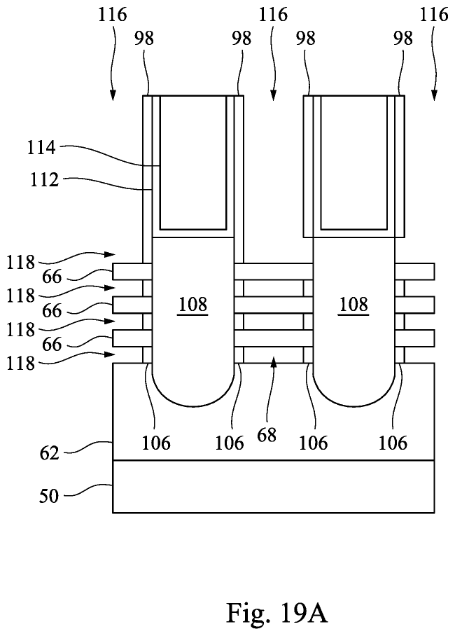

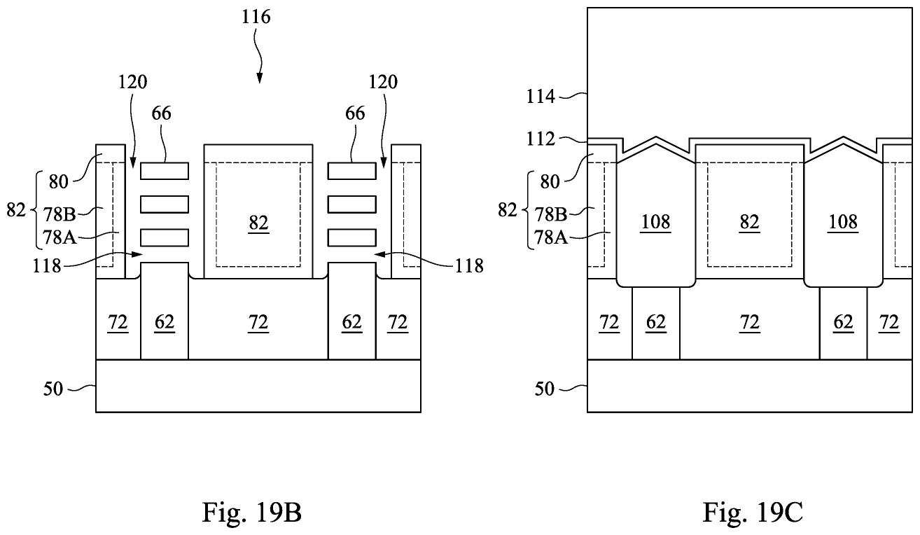

In FIGS. 19A-C, the masks 96 (if present) and the dummy gates 94 are removed in an etching process, so that recesses 116 are formed. In some embodiments, the dummy gates 94 are removed by an anisotropic dry etch process. For example, the etching process may include a dry etch process using reaction gas(es) that selectively etch the dummy gates 94 at a faster rate than the first ILD 114 or the gate spacers 98. Each recess 116 exposes and/or overlies portions of the channel regions 68. Portions of the nanostructures 66 which act as the channel regions 68 are disposed between adjacent pairs of the epitaxial source/drain regions 108.

The remaining portions of the nanostructures 64 are then removed to expand the recesses 116, such that openings 118 are formed in regions between the nanostructures 66. The remaining portions of the sacrificial spacers 76 are also removed to expand the recesses 116, such that openings 120 are formed in regions between semiconductor fins 62 and the insulating fins 82. The remaining portions of the nanostructures 64 and the sacrificial spacers 76 can be removed by any acceptable etching process that selectively etches the material(s) of the nanostructures 64 and the sacrificial spacers 76 at a faster rate than the material of the nanostructures 66. The etching may be isotropic. For example, when the nanostructures 64 and the sacrificial spacers 76 are formed of silicon germanium and the nanostructures 66 are formed of silicon, the etching process may be a wet etch using tetramethylammonium hydroxide (TMAH), ammonium hydroxide (NH₄OH), or the like. The masks 58 (if present) may also be removed. In some embodiments, a trim process (not separately illustrated) is performed to decrease the thicknesses of the exposed portions of the nanostructures 66.

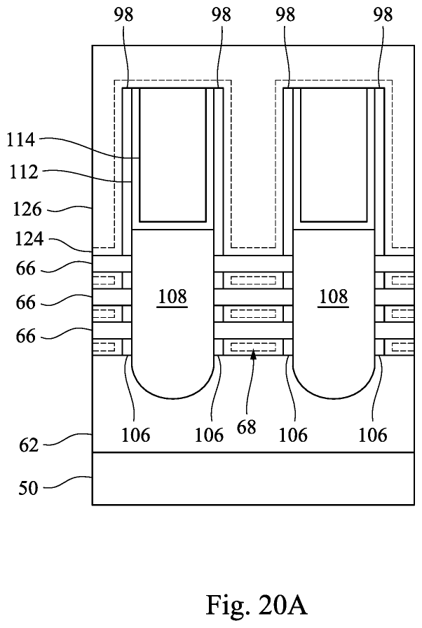

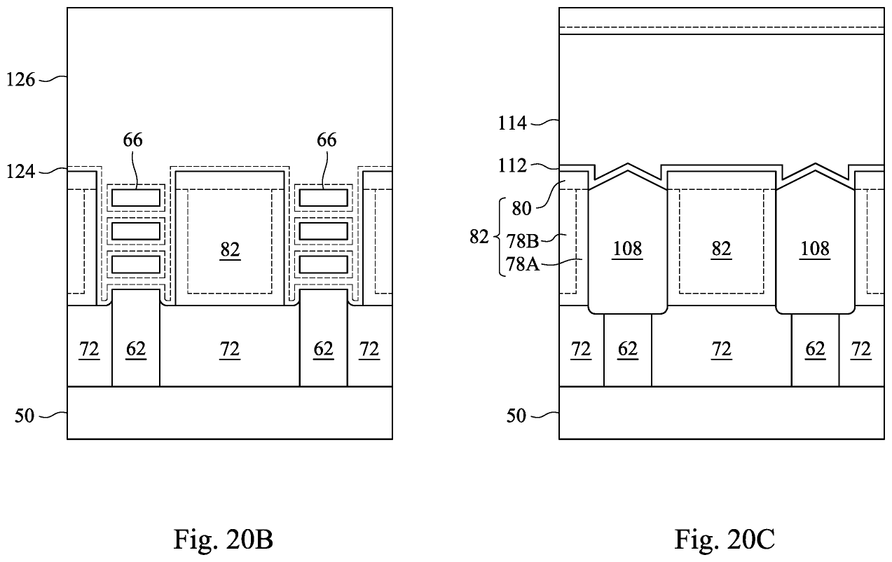

In FIGS. 20A-C, a gate dielectric layer 124 is formed in the recesses 116. A gate electrode layer 126 is formed on the gate dielectric layer 124. The gate dielectric layer 124 and the gate electrode layer 126 are layers for replacement gates, and each wrap around all (e.g., four) sides of the nanostructures 66. Thus, the gate dielectric layer 124 and the gate electrode layer 126 are formed in the openings 118 and the openings 120 (see FIGS. 19A-C).

The gate dielectric layer 124 is disposed on the sidewalls and/or the top surfaces of the semiconductor fins 62; on the top surfaces, the sidewalls, and the bottom surfaces of the nanostructures 66; on the sidewalls of the inner spacers 106 adjacent the epitaxial source/drain regions 108 and the gate spacers 98 on top surfaces of the top inner spacers 106; and on the top surfaces and the sidewalls of the insulating fins 82. The gate dielectric layer 124 may also be formed on the top surfaces of the first ILD 114 and the gate spacers 98. The gate dielectric layer 124 may include an oxide such as silicon oxide or a metal oxide, a silicate such as a metal silicate, combinations thereof, multi-layers thereof, or the like. The gate dielectric layer 124 may include a high-k dielectric material (e.g., a dielectric material having a k-value greater than about 7.0), such as a metal oxide or a metal silicate of hafnium, aluminum, zirconium, lanthanum, manganese, barium, titanium, lead, and combinations thereof. Although a single-layered gate dielectric layer 124 is illustrated, the gate dielectric layer 124 may include any number of interfacial layers and any number of main layers.

The gate electrode layer 126 may include a metal-containing material such as titanium nitride, titanium oxide, tantalum nitride, tantalum carbide, tungsten, cobalt, ruthenium, aluminum, combinations thereof, multi-layers thereof, or the like. Although a single-layered gate electrode layer 126 is illustrated, the gate electrode layer 126 may include any number of work function tuning layers, any number of barrier layers, any number of glue layers, and a fill material.

The formation of the gate dielectric layers 124 in the n-type region 50N and the p-type region 50P may occur simultaneously such that the gate dielectric layers 124 in each region are formed of the same materials, and the formation of the gate electrode layers 126 may occur simultaneously such that the gate electrode layers 126 in each region are formed of the same materials. In some embodiments, the gate dielectric layers 124 in each region may be formed by distinct processes, such that the gate dielectric layers 124 may be different materials and/or have a different number of layers, and/or the gate electrode layers 126 in each region may be formed by distinct processes, such that the gate electrode layers 126 may be different materials and/or have a different number of layers. Various masking steps may be used to mask and expose appropriate regions when using distinct processes.

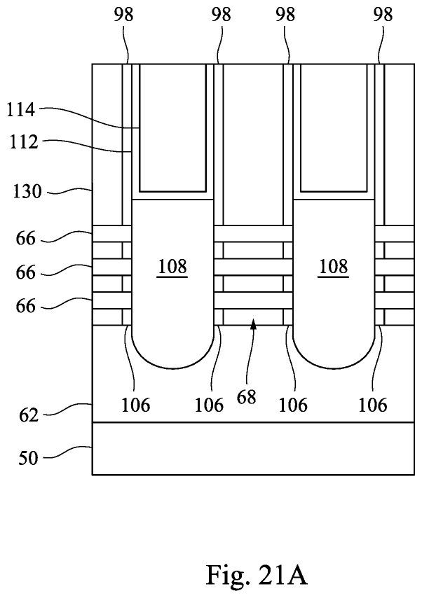

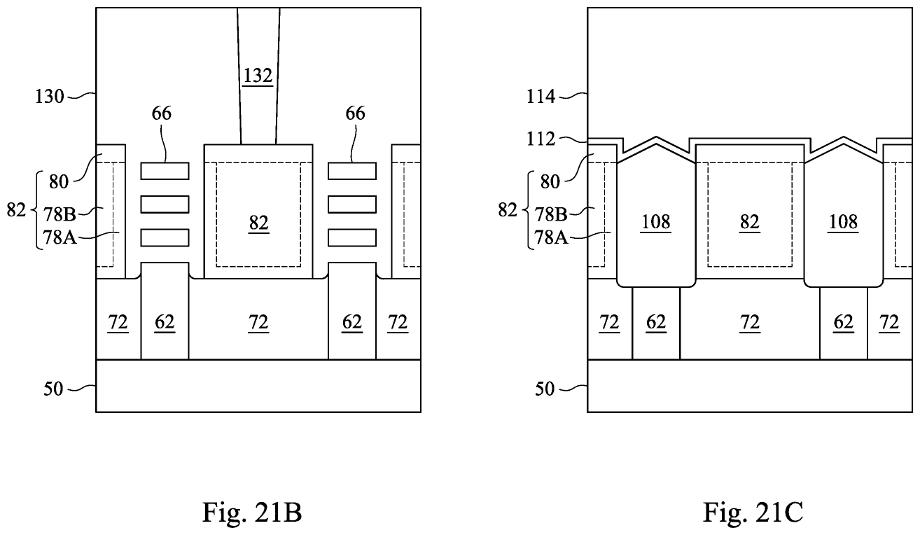

In FIGS. 21A-C, a removal process is performed to remove the excess portions of the materials of the gate dielectric layer 124 and the gate electrode layer 126, which excess portions are over the top surfaces of the first ILD 114 and the gate spacers 98, thereby forming gate structures 130. In some embodiments, a planarization process such as a chemical mechanical polish (CMP), an etch-back process, combinations thereof, or the like may be utilized. The gate dielectric layer 124, when planarized, has portions left in the recesses 116 and the openings 118, 120 (thus forming gate dielectrics for the gate structures 130). The gate electrode layer 126, when planarized, has portions left in the recesses 116 and the openings 118, 120 (thus forming gate electrodes for the gate structures 130). The top surfaces of the gate spacers 98; the CESL 112; the first ILD 114; and the gate structures 130 are coplanar (within process variations). The gate structures 130 are replacement gates of the resulting nano-FETs, and may be referred to as “metal gates.” The gate structures 130 each extend along top surfaces, sidewalls, and bottom surfaces of a channel region 68 of the nanostructures 66. The gate structures 130 fill the area previously occupied by the nanostructures 64, the sacrificial spacers 76, and the dummy gates 94.

In some embodiments, isolation regions 132 are formed extending through some of the gate structures 130. An isolation region 132 is formed to divide (or “cut”) a gate structure 130 into multiple gate structures 130. The isolation region 132 may be formed of a dielectric material, such as silicon nitride, silicon oxide, silicon oxynitride, or the like, which may be formed by a deposition process such as CVD, ALD, or the like. As an example to form the isolation regions 132, openings can be patterned in the desired gate structures 130. Any acceptable etch process, such as a dry etch, a wet etch, the like, or a combination thereof, may be performed to pattern the openings. The etching may be anisotropic. One or more layers of dielectric material may be deposited in the openings. A removal process may be performed to remove the excess portions of the dielectric material, which excess portions are over the top surfaces of the gate structures 130, thereby forming the isolation regions 132.

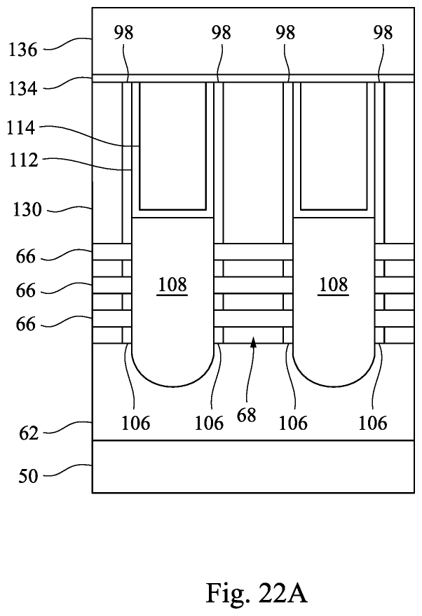

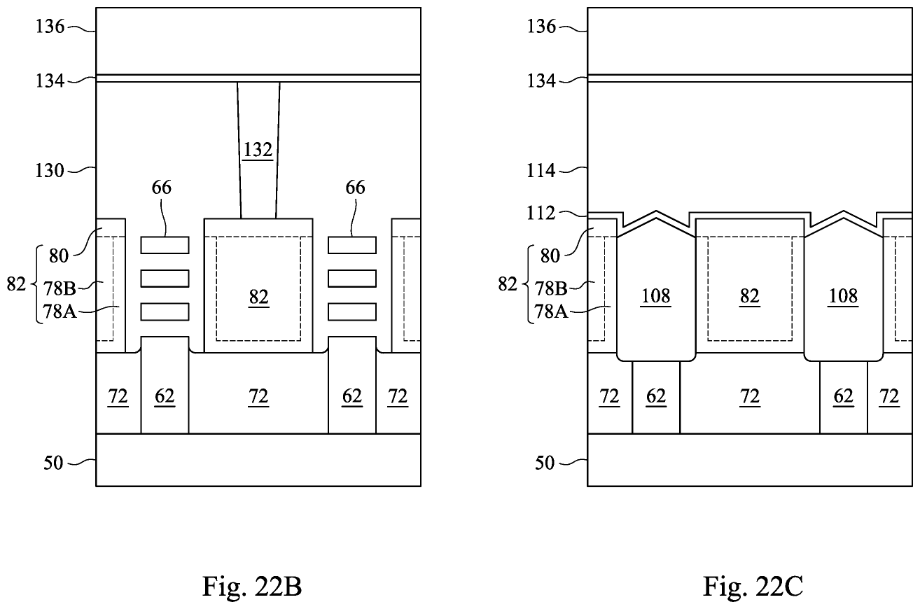

In FIGS. 22A-C, a second ILD 136 is deposited over the gate spacers 98, the CESL 112, the first ILD 114, and the gate structures 130. In some embodiments, the second ILD 136 is a flowable film formed by a flowable CVD method. In some embodiments, the second ILD 136 is formed of a dielectric material such as PSG, BSG, BPSG, USG, or the like, which may be deposited by any suitable method, such as CVD, PECVD, or the like.

In some embodiments, an etch stop layer (ESL) 134 is formed between the second ILD 136 and the gate spacers 98, the CESL 112, the first ILD 114, and the gate structures 130. The ESL 134 may include a dielectric material, such as silicon nitride, silicon oxide, silicon oxynitride, or the like, having a high etching selectivity from the etching of the second ILD 136.

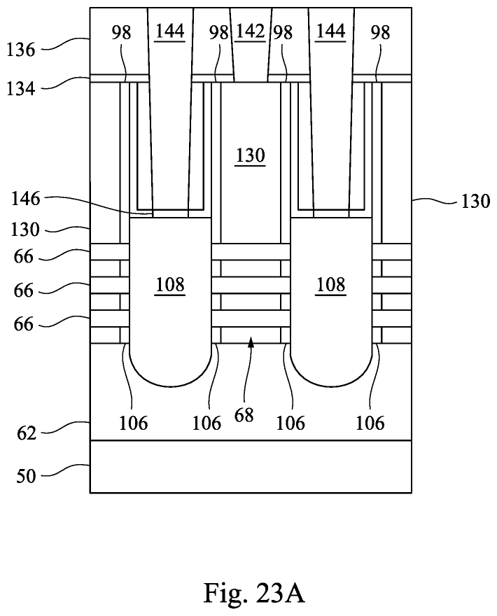

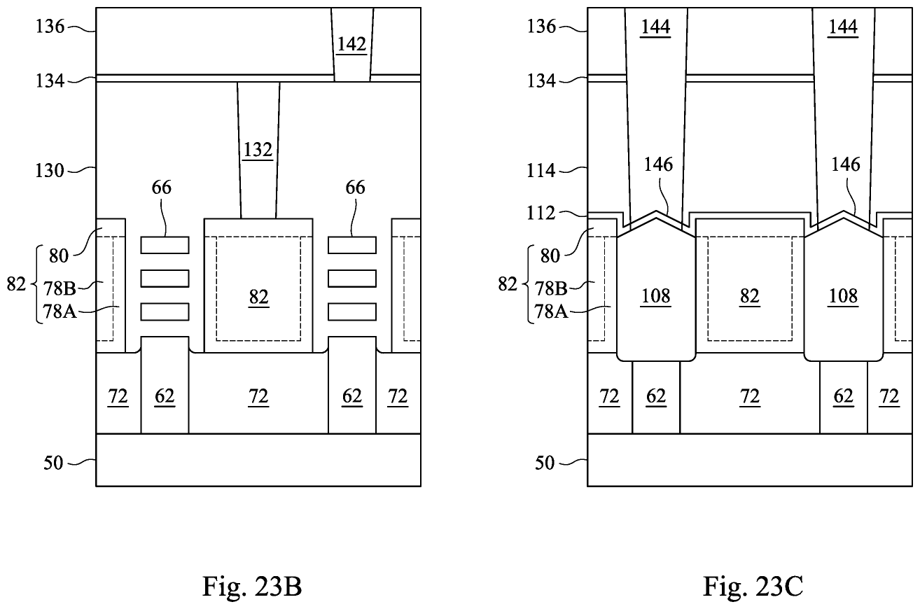

In FIGS. 23A-C, gate contacts 142 and source/drain contacts 144 are formed to contact, respectively, the gate structures 130 and the epitaxial source/drain regions 108. The gate contacts 142 are physically and electrically coupled to the gate structures 130. The source/drain contacts 144 are physically and electrically coupled to the epitaxial source/drain regions 108.

As an example to form the gate contacts 142 and the source/drain contacts 144, openings for the gate contacts 142 are formed through the second ILD 136 and the ESL 134, and openings for the source/drain contacts 144 are formed through the second ILD 136, the ESL 134, the first ILD 114, and the CESL 112. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 136. The remaining liner and conductive material form the gate contacts 142 and the source/drain contacts 144 in the openings. The gate contacts 142 and the source/drain contacts 144 may be formed in distinct processes, or may be formed in the same process. Although shown as being formed in the same cross-sections, it should be appreciated that each of the gate contacts 142 and the source/drain contacts 144 may be formed in different cross-sections, which may avoid shorting of the contacts.

Optionally, metal-semiconductor alloy regions 146 are formed at the interfaces between the epitaxial source/drain regions 108 and the source/drain contacts 144. The metal-semiconductor alloy regions 146 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 146 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the epitaxial source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 146. The material(s) of the source/drain contacts 144 can then be formed on the metal-semiconductor alloy regions 146.

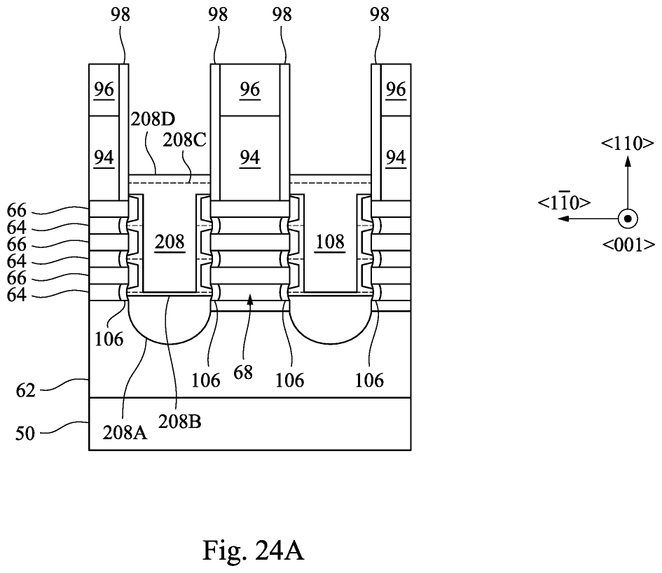

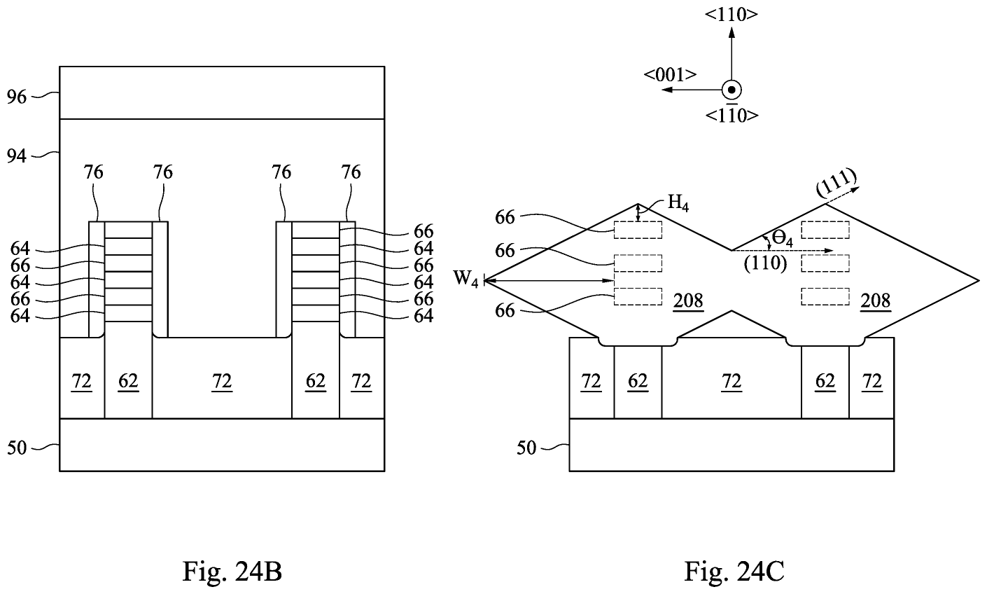

FIGS. 24A-C illustrate forming epitaxial source/drain regions 208 (e.g., in the p-type region 50P) in locations not bound on opposing sides by the insulating fins 82. The epitaxial source/drain regions 208 may be formed by the same or similar processes as described above in connection with the epitaxial source/drain regions 108. For example, although not separately illustrated, the epitaxial source/drain regions 208 may similarly include a liner layer 208A, a merging layer 208B, a main layer 208C, and a finishing layer 208D, as described above. In some embodiments, the epitaxial source/drain regions 208 are formed simultaneously with the epitaxial source/drain regions 108. After the epitaxy process, the epitaxial source/drain regions 208 may undergo one or more etching processes to reduce their sizes to the desired critical dimensions, such as reducing the lateral dimensions. In other embodiments, the epitaxial source/drain regions 208 are formed separately from the epitaxial source/drain regions 108. In those embodiments, the epitaxial source/drain regions 208 may be formed with a cyclic deposition and etching process or deposited using an epitaxy process and followed by one or more etching processes.

Without being bound by the insulating fins 82, the epitaxial source/drain regions 208 may extend farther laterally outward than the epitaxial source/drain regions 108. For example, in the cross-section illustrated in FIG. 24C, the epitaxial source/drain regions 208 may extend laterally outward beyond sidewalls of the semiconductor fins 62 and the nanostructures 66 by a width W₄ of between about 10 nm and about 26 nm. In addition, similarly as discussed above in connection with the epitaxial source/drain regions 108, upper facets of the epitaxial source/drain regions 208 along the {111} planes may be angled from the (110) plane by an angle θ₄ being between about 30° and about 50°, such as about 35.3°. The upper facets may reach a height H₄ above the topmost surface of the nanostructures 66 of between about 5 nm and about 12 nm, which is lower than if the epitaxial source/drain regions 208 were instead formed over a (001) oriented wafer. As a result, in embodiments in which a post-deposition etching process is performed for reduction and/or reshaping, the epitaxial source/drain regions 208 (e.g., unbounded by the insulating fins 82) and formed over the (110) oriented wafer have a smaller volume. The smaller volume contributes to less gate-to-drain capacitance and lower RC delay, thereby improving performance of the device.

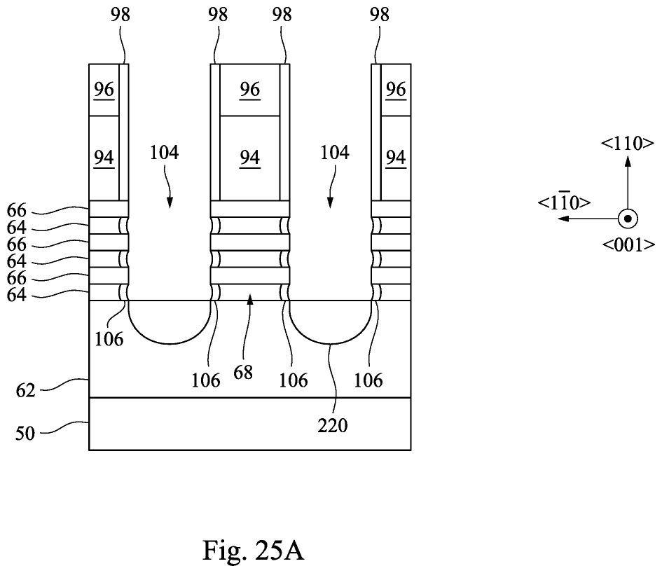

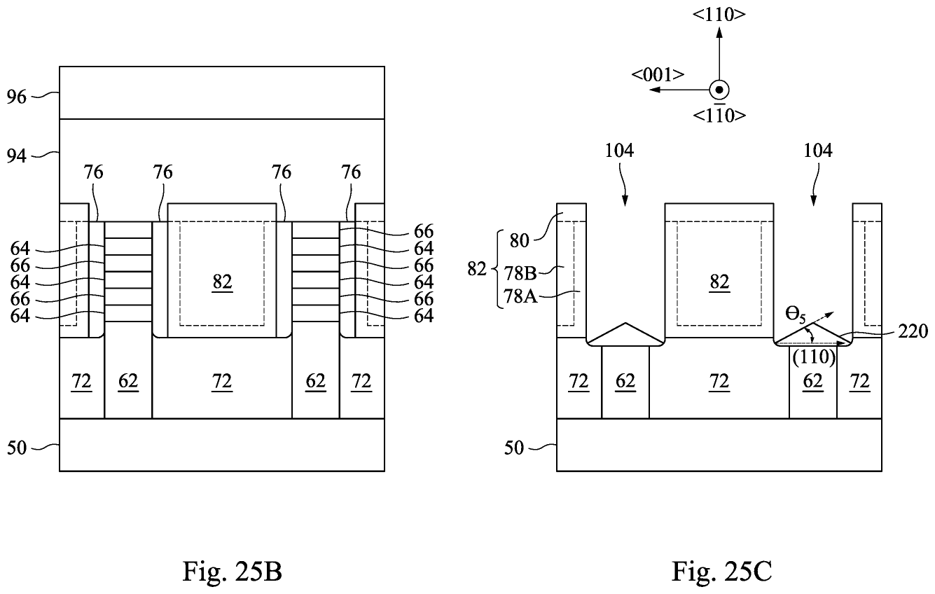

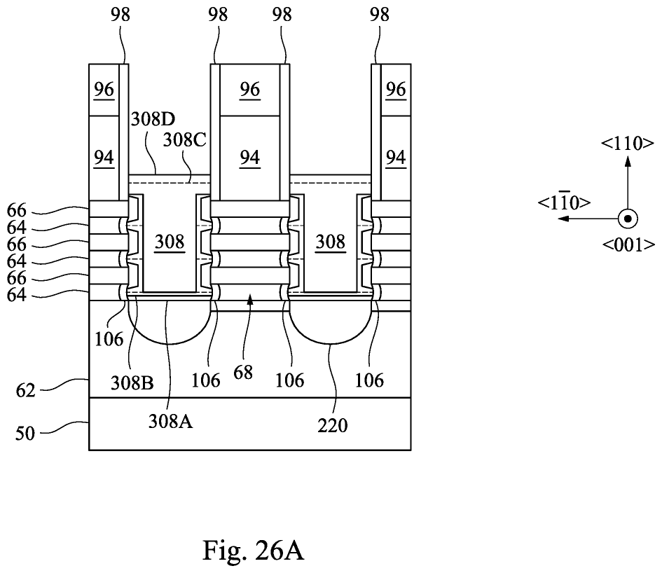

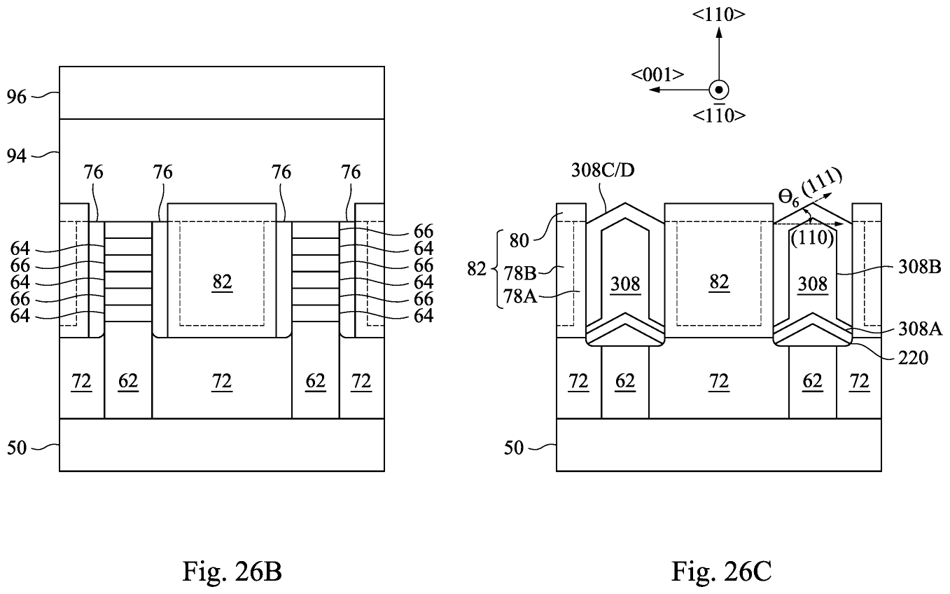

FIGS. 25A-26C illustrate an embodiment in which an undoped silicon layer 220 is formed in bottom portions of the source/drain recesses 104 before formation of epitaxial source/drain regions 308. Note that like reference numerals indicate like elements, which may be formed as described above in other embodiments. The undoped silicon layer 220 is formed with the same (110) orientation as the underlying semiconductor fins 62 and the substrate 50, thereby improving efficiency of the subsequent deposition of the epitaxial source/drain regions 308.

In FIGS. 25A-C, the undoped silicon layer 220 may be epitaxially grown along the bottom of the source/drain recesses 104 using, for example, CVD or any suitable process. The undoped silicon layer 220 reduces leakage current when the corresponding transistor (e.g., nano-FET) is in the “off” state. In the cross-section illustrated in FIG. 25C, upper facets of the undoped silicon layer 220 along the {111} planes may be angled from the (110) plane by an angle θ₅ being between about 30° and about 50°, such as about 35.3°, similarly as described above in connection with the upper facets of the epitaxial source/drain regions 108. Although not specifically illustrated, in some embodiments, portions of the undoped silicon 220 may also form along the exposed surfaces of the nanostructures 66. However, adjustments of process parameters may prevent or minimize any formation of undoped silicon 220 along the exposed surfaces of the nanostructures 66.

In FIGS. 26A-C, the epitaxial source/drain regions 308 are formed over the undoped silicon layer 220 in the source/drain recesses 104 similarly as described above in connection with the epitaxial source/drain regions 108. For example, the epitaxial source/drain regions 308 may similarly include a liner layer 308A, a merging layer 308B, a main layer 308C, and a finishing layer 308D, as described above. As illustrated, upper facets of the epitaxial source/drain region 308 along the {111} planes may be angled from the (110) plane by an angle θ₆ being between about 30° and about 50°, such as about 35.3° by following the crystallography of the underlying portions (e.g., the undoped silicon layer 220, the semiconductor fins 62, and the substrate 50).

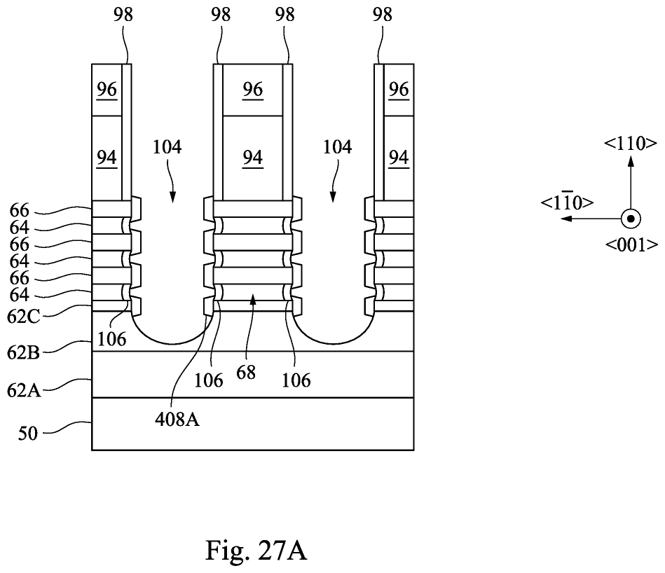

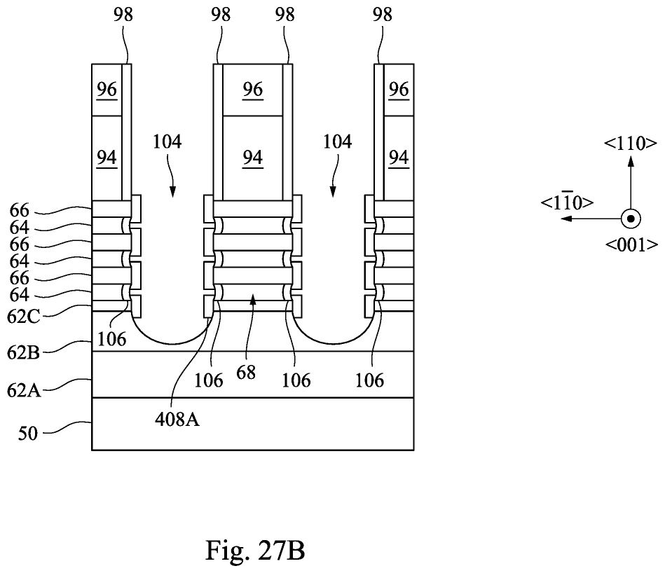

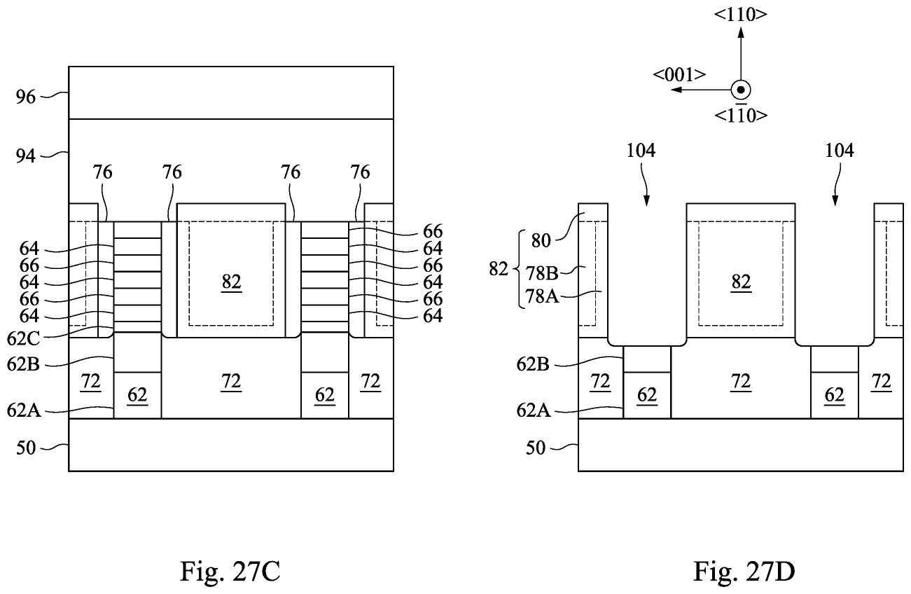

FIGS. 27A-29D illustrate an embodiment in which epitaxial source/drain regions 408 are formed over semiconductor fins 62 that had been formed over and/or in a semiconductor-on-insulator (SOI) substrate. Note that like reference numerals indicate like elements, which may be formed as described above in other embodiments. In some embodiments, uppermost portions of the semiconductor fins 62 comprise insulator material of the SOI substrate. As a result, the epitaxial source/drain regions 408 may form on sidewalls of the nanostructures 66 but not on the exposed surfaces of the semiconductor fins 62 (e.g., the insulator material) in the source/drain recesses 104.

For example, the substrate 50 is converted into a SOI substrate before forming the multi-layer stack 52 of the first semiconductor layers 54 and the second semiconductor layers 56 and, therefore, before forming the semiconductor fins 62. The resulting substrate 50 may include a lowermost substrate region comprising silicon, a middle insulator region comprising an oxide, nitride, or combinations thereof, and an uppermost silicon region comprising silicon. As illustrated in FIGS. 27A-27C, the semiconductor fins 62 formed in the SOI substrate may then include a lowermost substrate region 62A (e.g., comprising a semiconductor such as silicon), a middle insulator region 62B (e.g., comprising an oxide, nitride, or combinations thereof), and an uppermost silicon region 62C (e.g., comprising a semiconductor such as silicon, which may be doped as described above in connection with the nanostructures 64, 66).

In some embodiments, the SOI substrate is formed using an implantation process, such as using an ion beam to implant oxygen into the substrate 50 at a specified range of depths, or any suitable process. The implantation process is then followed by a high temperature anneal, which together creates a buried SiO₂ layer as the middle insulator region of the SOI substrate (e.g., subsequently the middle insulator region 62b of the semiconductor fins 62). The lowermost substrate region (e.g., subsequently the lowermost substrate region 62A of the semiconductor fins 62) is the part of the substrate 50 below the middle insulator region, and the uppermost silicon region (e.g., subsequently the uppermost silicon region 62C of the semiconductor fins 62) is the part of the substrate 50 above the middle insulator region.

In other embodiments, a different silicon wafer (not separately illustrated) is oxidized to form an insulator material (e.g., SiO₂), and the different silicon wafer is bonded to the substrate 50. After the bonding process, a majority of the silicon of the different silicon wafer may be removed by grinding, CMP, or any suitable process. As a result, the insulator material forms the middle insulator region (e.g., subsequently the middle insulator region 62B of the semiconductor fins 62), the silicon of the substrate 50 is the lowermost substrate region (e.g., subsequently the lowermost substrate region 62A of the semiconductor fins 62), and the remaining silicon of the different silicon wafer is the uppermost silicon region (e.g., subsequently the uppermost silicon region 62C of the semiconductor fins 62).

In FIGS. 27A-D, the source/drain recesses 104 may be formed similarly as described above to extend into the semiconductor fins 62, including a portion of the substrate 50. As illustrated, the source/drain recesses 104 may extend entirely through the uppermost silicon region 62C to expose top surfaces of the middle insulator region 62B. In some embodiments, the source/drain recesses 104 may extend partially through the middle insulator region 62B. As a result, bottom portions of the source/drain recesses 104 will not include top surfaces of semiconductor material on which the subsequently formed epitaxial source/drain regions 408 will epitaxially grow.

In addition, liner layer 408A is formed in the source/drain recesses 104 similarly as described above in connection with the epitaxial source/drain regions 108 (see FIGS. 14A-G). Discrete portions of the liner layer 408A form over the nanostructures 66 and extend partially over the inner spacers 106. The discrete portions may comprise trapezoidal shapes (see FIG. 27A), rectangular shapes (see FIG. 27B), or combinations thereof. In addition, lowermost discrete portions of the liner layer 408A on exposed sidewall surfaces of the uppermost silicon region 62C may laterally extend along and over portions of the middle insulator regions 62B just as uppermost discrete portions of the liner layer 108A may laterally extend along and over portions of the gate spacers 98. As noted above, other than the lowermost discrete portions of the liner layer 408A, exposed surfaces of the middle insulator region 62B remains substantially free of the liner layer 408A. The liner layer 408A may otherwise epitaxially grow similarly as described above in connection with FIGS. 14A-G.

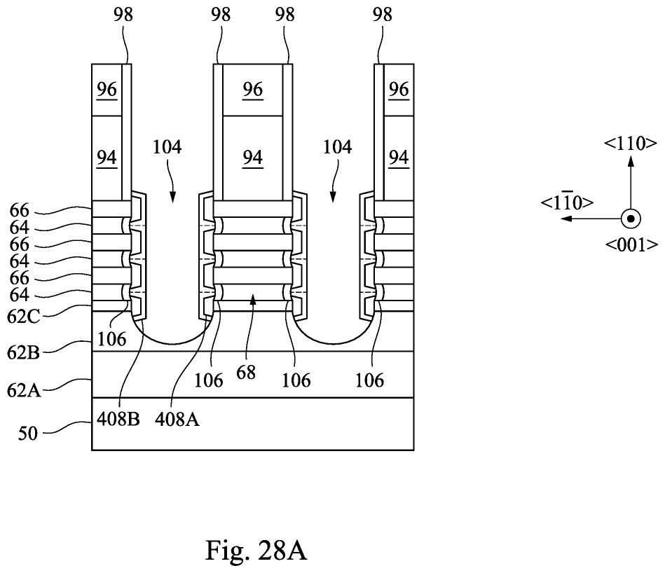

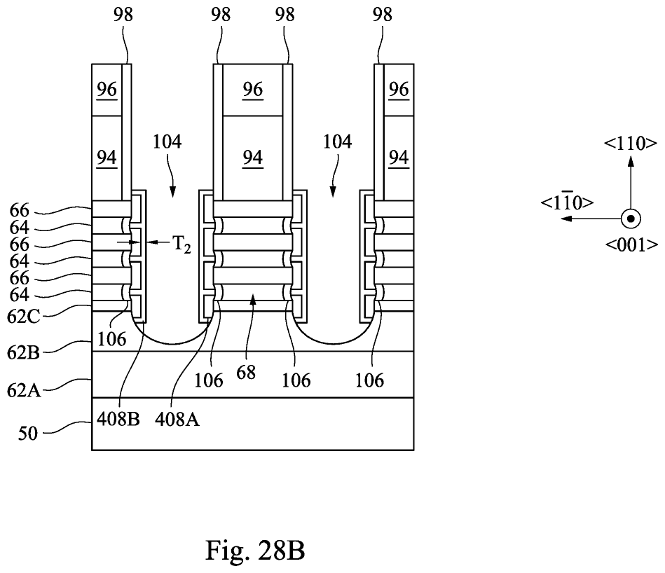

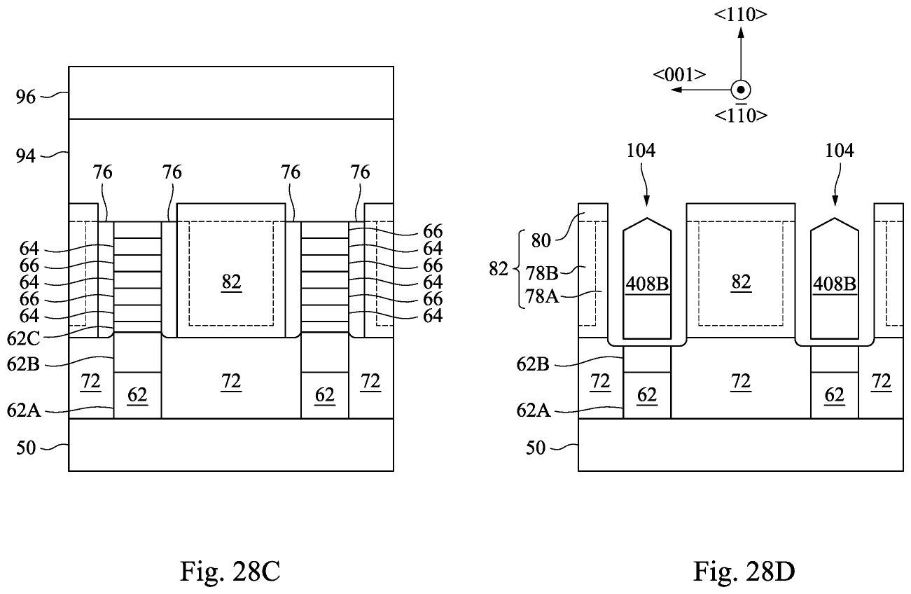

In FIGS. 28A-D, merging layer 408B is formed in the source/drain recesses 104 similarly as described above in connection with the epitaxial source/drain regions 108 (see FIGS. 15A-D). The merging layer 208B connects (or merges) adjacent ones of the discrete portions of the liner layer 408A along sidewalls of the source/drain recesses 104. In the cross-section illustrated in FIGS. 28A-B, the merging layer 408B may not yet extend entirely across the source/drain recesses 104 due to the bottom portions of the source/drain recesses 104 (e.g., along the exposed surfaces of the middle insulator region 62B) due to not having semiconductor material to facilitate epitaxial growth of the liner layer 408A and the merging layer 408B. The merging layer 408B may otherwise epitaxially grow similarly as described above in connection with FIGS. 15A-D.

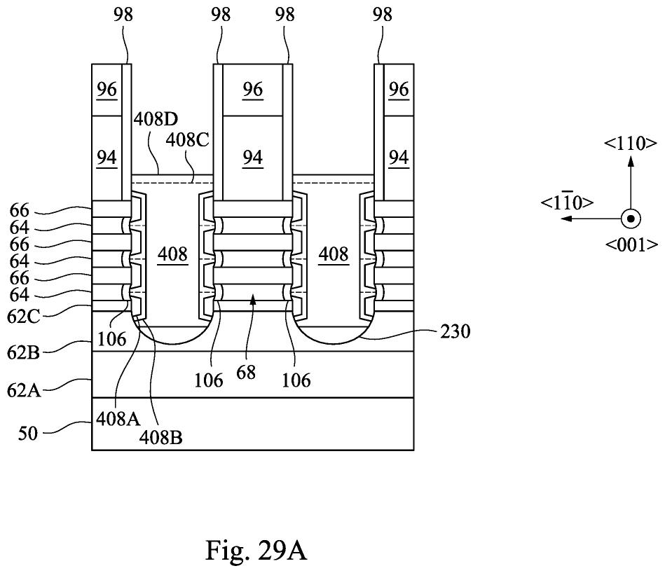

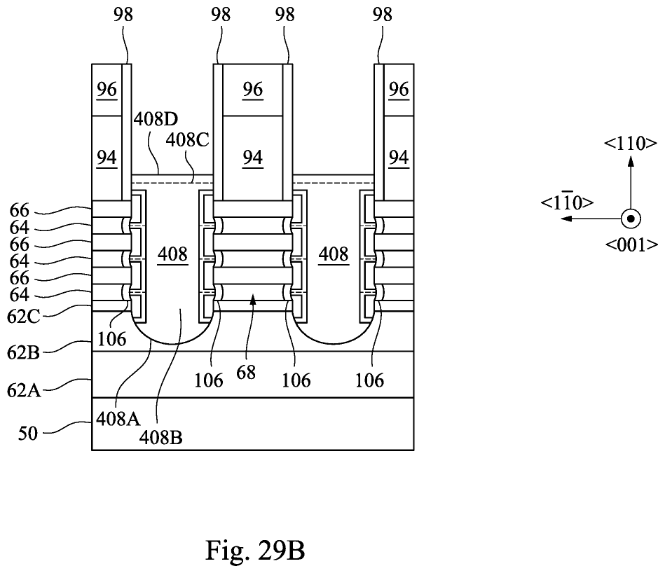

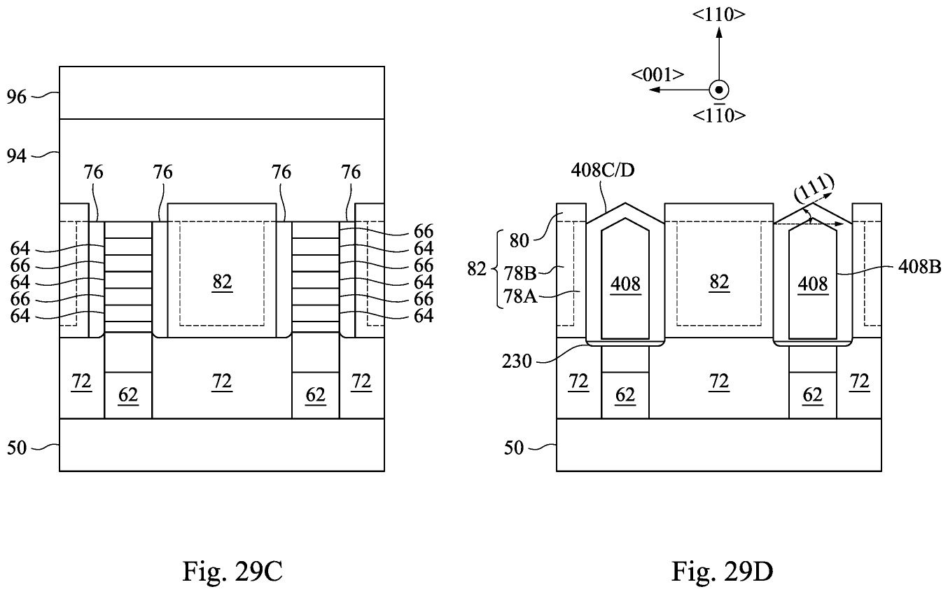

In FIGS. 29A-D, main layer 408C and finishing layer 408D are formed over the merging layer 408B similarly as described above in connection with the epitaxial source/drain regions 108 (see FIGS. 16A-D), which may form a void 230 (e.g., an air void) along the bottom portions of the source/drain recesses 104. The void 230 may be disposed between bottoms of the epitaxial source/drain regions 108 and the insulator region 62B of the fin 62. As illustrated, the main layer 408C and the finishing layer 408D connect separated portions of the liner layer 408A and the merging layer 408B as well as fill a majority of each of the source/drain recesses 104. Although the main layer 408C forms over the merging layer 408B in locations proximal to the bottom portions of the source/drain recesses 104, the main layer 408C may not entirely fill those bottom portions, thereby leaving the voids 230 as discussed above. The main layer 408C and the finishing layer 408D may otherwise epitaxially grow similarly as described above in connection with FIGS. 16A-D.

In various embodiments, advantages are achieved in the formation of semiconductor devices (e.g., nano-FETs). In particular, the epitaxial source/drain regions 108 (including, hereinafter, the epitaxial source/drain regions 208/308/408) of the semiconductor devices are formed such that initial discrete portions, such as the liner layer 108A, may form along the nanostructures 66 in trapezoidal and/or rectangular shapes. Epitaxial growth of the trapezoidal and/or rectangular shapes proceeds faster and more efficiently. In addition, as subsequent layers of the epitaxial source/drain regions 108 are formed (e.g., the merging layer 108B, the main layer 108C, and the finishing layer 108D), the discrete portions merge and follow the underlying crystallographic patterns. The resulting epitaxial source/drain regions 108 may have flatter upper facets, such as less than 50° angles from the substrate 50 and, therefore, may occupy less volume than if the upper facets had angles of greater than 50°. The decreased volume results in decreased gate-to-drain capacitance C_{GD}, thereby improving RC delay and performance of the semiconductor devices. Further, the faster growth and decreased final volume of the epitaxial source/drain regions 108 contribute to improved efficiency and yield in the fabrication of the semiconductor devices (e.g., reducing production costs).

As discussed above, the trapezoidal and/or rectangular shapes as well as the decreased volume of the epitaxial source/drain regions 108 may be achieved, for example, by starting with a (110) crystallographic oriented silicon wafer (e.g., the substrate 50) on which the semiconductor devices (e.g., nano-FETs) are formed. Nanostructures 64, 66 formed (e.g., epitaxially grown) over the substrate 50 and may follow the (110) crystallographic orientation. As a result, the nanostructures 66 that subsequently form channel regions of the semiconductor devices will have higher hole mobility in the <110> direction. The higher hole mobility in the nanostructures 66 contributes to greater effective inverter current I_{Deff} from one epitaxial source/drain region 108 to another epitaxial source/drain region 108 through those channel regions. The greater effective inverter current I_{Deff} results in improved device performance.

In an embodiment, a method includes depositing a first semiconductor layer and a second semiconductor layer over a substrate; patterning the first semiconductor layer, the second semiconductor layer, and the substrate to form a first nanostructure, a second nanostructure, and a semiconductor fin; forming a recess in the first nanostructure and the second nanostructure, the recess exposing the semiconductor fin; epitaxially growing a first layer in the recess, a first portion of the first layer being disposed along a first sidewall of the first nanostructure, a second portion of the first layer being disposed along the semiconductor fin, the first portion of the first layer comprising two sidewalls extending toward a middle of the recess, the first portion of the first layer further comprising a first surface most distal from the first sidewall and directly interposed between the two sidewalls, the first portion being physically separated from the second portion; and epitaxially growing a second layer over the first portion of the first layer and over the second portion of the first layer, the second layer physically connecting the first portion of the first layer to the second portion of the first layer. In another embodiment, a material of the substrate has a (110) crystallographic orientation. In another embodiment, each of a material of the first nanostructure and a material of the second nanostructure has a (110) crystallographic orientation. In another embodiment, the method further includes forming a first insulating fin and a second insulating fin over the substrate, the recess being interposed between the first insulating fin and the second insulating fin. In another embodiment, the first insulating fin and the second insulating fin remain free of the first portion of the first layer, and wherein the first insulating fin and the second insulating fin physically contact the second portion of the first layer. In another embodiment, the method further includes forming an inner spacer over a second sidewall of the first nanostructure, wherein the first portion of the first layer extends over and physically contacts a surface of the inner spacer, and wherein the second portion of the first layer extends over and physically contacts the surface of the inner spacer. In another embodiment, the second layer physically contacts the surface of the inner spacer. In another embodiment, the method further includes, before epitaxially growing the first layer, epitaxially growing an undoped silicon layer in the recess along the semiconductor fin.

In an embodiment, a semiconductor device includes first nanostructures disposed directly over a first portion of a semiconductor fin; second nanostructures disposed directly over a second portion of the semiconductor fin; a first gate structure disposed between and directly over the first nanostructures; a second gate structure disposed between and directly over the second nanostructures; and an epitaxial source/drain region being interposed between the first nanostructures and the second nanostructures, the epitaxial source/drain region includes a first discrete portion physically contacting the first gate structure, the first discrete portion having a first composition; a second discrete portion physically contacting the second gate structure, the second discrete portion having the first composition; a third discrete portion below the first discrete portion and the second discrete portion, the third discrete portion having the first composition, wherein the first discrete portion, the second discrete portion, and the third discrete portion are physically separate from each other; a merging layer physically contacting the first discrete portion, the second discrete portion, and the third discrete portion, the merging layer having a second composition different from the first composition; and a main layer physically contacting the merging layer and interposed between the first discrete portion and the second discrete portion, the main layer having a third composition different from the first composition and the second composition. In another embodiment, the first discrete portion includes a first sidewall facing the first gate structure; a second sidewall opposite the first sidewall; a top surface connecting the first sidewall to the second sidewall; and a bottom surface connecting the first sidewall to the second sidewall. In another embodiment, the first composition has a first germanium concentration. In another embodiment, the second composition has a second germanium concentration greater than the first germanium concentration. In another embodiment, the second composition is silicon germanium, and wherein the third composition is silicon germanium. In another embodiment, the main layer comprises two upper facets, and wherein each of the two upper facets is angled by between about 30° and about 50° from major planes of the first nanostructures and of the second nano structures.

In an embodiment, a semiconductor device includes a fin disposed over a substrate and interposed between isolation regions, the substrate having a (110) crystallographic orientation; a nanostructure disposed over the fin; a gate electrode being interposed between the fin and the nanostructure; and a source/drain region disposed over the fin and laterally displaced from the nanostructure, the source/drain region includes a first layer comprising a first sidewall physically contacting the nanostructure, the first layer further comprising a second sidewall opposite and laterally displaced from the first sidewall; and a second layer disposed over and around the first layer. In another embodiment, the semiconductor device further includes a silicon region interposed between the source/drain region and the fin. In another embodiment, the semiconductor device further includes a void interposed between the source/drain region and the fin. In another embodiment, the fin comprises an insulator region exposed to the void. In another embodiment, the source/drain region comprises a facet most distal from the fin, the facet having an angle of between about 30° and about 50° from a major surface of the substrate. In another embodiment, the semiconductor device further includes a first insulating fin and a second insulating fin physically contacting opposing sidewalls of the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a first semiconductor layer and a second semiconductor layer over a substrate;
patterning the first semiconductor layer, the second semiconductor layer, and the substrate to form a first nanostructure, a second nanostructure, and a semiconductor fin;
forming a recess in the first nanostructure and the second nanostructure, the recess exposing the semiconductor fin;
epitaxially growing a first layer in the recess, a first portion of the first layer being disposed along a first sidewall of the first nanostructure, a second portion of the first layer being disposed along the semiconductor fin, the first portion of the first layer comprising two sidewalls extending toward a middle of the recess, the first portion of the first layer further comprising a first surface most distal from the first sidewall and directly interposed between the two sidewalls, the first portion being physically separated from the second portion; and
epitaxially growing a second layer over the first portion of the first layer and over the second portion of the first layer, the second layer physically connecting the first portion of the first layer to the second portion of the first layer.

2. The method of claim 1, wherein a material of the substrate has a (110) crystallographic orientation.

3. The method of claim 2, wherein each of a material of the first nanostructure and a material of the second nanostructure has a (110) crystallographic orientation.

4. The method of claim 1 further comprising forming a first insulating fin and a second insulating fin over the substrate, the recess being interposed between the first insulating fin and the second insulating fin.

5. The method of claim 4, wherein the first insulating fin and the second insulating fin remain free of the first portion of the first layer, and wherein the first insulating fin and the second insulating fin physically contact the second portion of the first layer.

6. The method of claim 1 further comprising forming an inner spacer over a second sidewall of the first nanostructure, wherein the first portion of the first layer extends over and physically contacts a surface of the inner spacer, and wherein the second portion of the first layer extends over and physically contacts the surface of the inner spacer.

7. The method of claim 6, wherein the second layer physically contacts the surface of the inner spacer.

8. The method of claim 1 further comprising, before epitaxially growing the first layer, epitaxially growing an undoped silicon layer in the recess along the semiconductor fin.

9. A semiconductor device comprising:
first nanostructures disposed directly over a first portion of a semiconductor fin;
second nanostructures disposed directly over a second portion of the semiconductor fin;
a first gate structure disposed between and directly over the first nanostructures;
a second gate structure disposed between and directly over the second nanostructures; and
an epitaxial source/drain region being interposed between the first nanostructures and the second nanostructures, the epitaxial source/drain region comprising:
a first discrete portion physically contacting the first gate structure, the first discrete portion having a first composition;
a second discrete portion physically contacting the second gate structure, the second discrete portion having the first composition;
a third discrete portion below the first discrete portion and the second discrete portion, the third discrete portion having the first composition, wherein the first discrete portion, the second discrete portion, and the third discrete portion are physically separate from each other;
a merging layer physically contacting the first discrete portion, the second discrete portion, and the third discrete portion, the merging layer having a second composition different from the first composition; and
a main layer physically contacting the merging layer and interposed between the first discrete portion and the second discrete portion, the main layer having a third composition different from the first composition and the second composition.

10. The semiconductor device of claim 9, wherein the first discrete portion comprises:
a first sidewall facing the first gate structure;
a second sidewall opposite the first sidewall;
a top surface connecting the first sidewall to the second sidewall; and
a bottom surface connecting the first sidewall to the second sidewall.

11. The semiconductor device of claim 9, wherein the first composition has a first germanium concentration.

12. The semiconductor device of claim 11, wherein the second composition has a second germanium concentration greater than the first germanium concentration.

13. The semiconductor device of claim 9, wherein the second composition is silicon germanium, and wherein the third composition is silicon germanium.

14. The semiconductor device of claim 9, wherein the main layer comprises two upper facets, and wherein each of the two upper facets is angled by between about 30° and about 50° from major planes of the first nanostructures and of the second nanostructures.

15. A semiconductor device comprising:
a fin disposed over a substrate and interposed between isolation regions, the substrate having a (110) crystallographic orientation;
a nanostructure disposed over the fin;
a gate electrode being interposed between the fin and the nanostructure; and
a source/drain region disposed over the fin and laterally displaced from the nanostructure, the source/drain region comprising:
a first layer comprising a first sidewall physically contacting the nanostructure, the first layer further comprising a second sidewall opposite and laterally displaced from the first sidewall; and
a second layer disposed over and around the first layer.

16. The semiconductor device of claim 15 further comprising a silicon region interposed between the source/drain region and the fin.

17. The semiconductor device of claim 15 further comprising a void interposed between the source/drain region and the fin.

18. The semiconductor device of claim 17, wherein the fin comprises an insulator region exposed to the void.

19. The semiconductor device of claim 15, wherein the source/drain region comprises a facet most distal from the fin, the facet having an angle of between about 30° and about 50° from a major surface of the substrate.

20. The semiconductor device of claim 15 further comprising a first insulating fin and a second insulating fin physically contacting opposing sidewalls of the source/drain region.
